(19) United States
(12) Patent Application Publication
(10) Pub. No.: US 2025/0096787 A1
(43) Pub. Date: Mar. 20, 2025

(54) MULTI-LEVEL DRIVING FOR EFFICIENT SWITCHING REGULATORS

(71) Applicant: Intel Corporation, Santa Clara, CA (US)

(72) Inventor: Sally Safwat Amin, Hillsboro, OR (US)

(21) Appl. No.: 18/467,495

(22) Filed: Sep. 14, 2023

(51) Int. Cl. H03K 17/06; H03K 17/687

(52) U.S. Cl. CPC H03K 17/063; H03K 17/687; H03K 2217/0063; H03K 2217/0072

(57) ABSTRACT

Embodiments herein relate to a driver for a voltage converter which efficiently generates a control gate voltage of a power switch. The driver applies a staircase increasing and decreasing voltage to the control gate with three or more voltage levels, including an initial level such as 0 V, one or more intermediate voltages, and a peak drive voltage. The one or more intermediate voltages can be generated by a charge-recycling circuit which can include push-pull capacitors or switched flying capacitors. The push-pull capacitors are provided in a number of push-pull regulation circuits which is equal to the number of intermediate voltages. The switched flying capacitors are provided in a circuit where the number of flying capacitors is equal to the number of intermediate voltages.

### FIELD

The present application generally relates to the field of direct current-to-direct current (DC-DC) voltage converters.

### BACKGROUND

DC-to-DC voltage converters, also referred to as power converters, are useful for converting a power supply at one voltage to another voltage. For example, a voltage converter can convert the main supply voltage of a computing device, such as 12 V, down to lower voltages, such as 5 V, 3.3 V or 1.8 V. The lower voltages can be used by various components in the computing device. These components can include a Universal Serial Bus (USB) interface, memory such as dynamic random access memory (DRAM) and processing resources such as a central processing unit (CPU). However, various challenges are presented in operating a voltage converter.

### BRIEF DESCRIPTION OF THE DRAWINGS

The embodiments of the disclosure will be understood more fully from the detailed description given below and from the accompanying drawings of various embodiments of the disclosure, which, however, should not be taken to limit the disclosure to the specific embodiments, but are for explanation and understanding only.

FIG. 1A depicts an example voltage regulator (VR) 100 including a two-level driver, in accordance with various embodiments.

FIG. 1B depicts an example plot of the output voltage Vg versus time for the driver of FIG. 1A, in accordance with various embodiments.

FIG. 2A depicts an example VR 200 including a multi-level driver 210 with a charge-recycling circuit 220, in accordance with various embodiments.

FIG. 2B depicts an example plot of the output voltage Vg versus time for the driver of FIG. 2A, in accordance with various embodiments.

FIG. 2C depicts an example plot of gate switching loss (Ploss) reduction versus number of voltage steps (N) for the driver of FIG. 2A, in accordance with various embodiments.

FIG. 3A1 depicts an example three-level driver 300 with two voltage sources, in accordance with various embodiments.

FIG. 3A2 depicts an example plot of the output voltage Vg versus time for the driver of FIG. 3A1, in accordance with various embodiments.

FIG. 3B1 depicts an example four-level driver 340 with three voltage sources, in accordance with various embodiments.

FIG. 3B2 depicts an example plot of the output voltage Vg versus time for the driver of FIG. 3B1, in accordance with various embodiments.

FIG. 3C1 depicts an example five-level driver 380 with four voltage sources, in accordance with various embodiments.

FIG. 3C2 depicts an example plot of the output voltage Vg versus time for the driver of FIG. 3C1, in accordance with various embodiments.

FIG. 4A1 depicts an example three-level driver 400 with digital push-pull regulation for charge recycling, consistent with the charge-recycling circuit 220 of FIG. 2A, in accordance with various embodiments.

FIG. 4A2 depicts an example plot of the output voltage Vg versus time for the driver of FIG. 4A1, in accordance with various embodiments.

FIG. 4B1 depicts an example four-level driver 420 with digital push-pull regulation for charge recycling, consistent with the charge-recycling circuit 220 of FIG. 2A, in accordance with various embodiments.

FIG. 4B2 depicts an example plot of the output voltage Vg versus time for the driver of FIG. 4B1, in accordance with various embodiments.

FIG. 4C1 depicts an example five-level driver 445 with digital push-pull regulation for charge recycling, consistent with the charge-recycling circuit 220 of FIG. 2A, in accordance with various embodiments.

FIG. 4C2 depicts an example plot of the output voltage Vg versus time for the driver of FIG. 4C1, in accordance with various embodiments.

FIG. 5A1 depicts an example switched capacitor-based three-level driver 550, consistent with the charge-recycling circuit 220 of FIG. 2A, in accordance with various embodiments.

FIG. 5A2 depicts an example plot of the output voltage Vg versus time for the driver of FIG. 5A1, in accordance with various embodiments.

FIG. 5B1 depicts an example switched capacitor-based four-level driver 570, consistent with the charge-recycling circuit 220 of FIG. 2A, in accordance with various embodiments.

FIG. 5B2 depicts an example plot of the output voltage Vg versus time for the driver of FIG. 5B1, in accordance with various embodiments.

FIG. 5C1 depicts an example switched capacitor-based five-level driver 590, consistent with the charge-recycling circuit 220 of FIG. 2A, in accordance with various embodiments.

FIG. 5C2 depicts an example plot of the output voltage Vg versus time for the driver of FIG. 5C1, in accordance with various embodiments.

FIG. 6A depicts plots of gate voltage versus time for different numbers of voltage steps (N), in accordance with various embodiments.

FIG. 6B depicts a plot of efficiency improvement versus number of voltage steps (N), in accordance with various embodiments.

FIG. 7A depicts a plot of a flying capacitor voltage (Vf) versus time for a three-level driver, consistent with FIG. 5A1, in accordance with various embodiments.

FIG. 7B depicts a plot of a control gate voltage (Vg), consistent with FIG. 7A, in accordance with various embodiments.

FIG. 8A depicts a plot of a flying capacitor voltage ripple versus capacitance ratio for different numbers of voltage steps (N), consistent with FIGS. 5A1, 5B1 and 5C1, in accordance with various embodiments.

FIG. 8B depicts a plot of a main driver Ploss reduction versus capacitance ratio for different numbers of voltage steps (N), consistent with FIG. 8A, in accordance with various embodiments.

FIG. 9 depicts an example DC-to-DC voltage converter 900 which includes a high-side drive (HSD) and a low-side driver (LSD), in accordance with various embodiments.

FIG. 10 illustrates an example of components that may be present in a computing system 950 for implementing the techniques (e.g., operations, processes, methods, and methodologies) described herein.

### DETAILED DESCRIPTION

As mentioned at the outset, various challenges are presented in operating a voltage converter.

High-voltage, high-frequency DC-DC voltage converters (also referred to as voltage regulators VRs) can provide improved load line performance, high power density, reduced inductor size, and high end-to-end efficiency. These voltage converters may be arranged, e.g., in an integrated circuit, a System in Package (SiP), a System on a Chip (SoC), or a stacked tile/chiplet design which includes multiple integrated circuits/chips within the same package.

However, a number of challenges are presented. For example, as the input voltage increases and the switching frequency, Fsw, is pushed higher to tens of MHz, the efficiency is compromised due to high switching losses. Additionally, supporting higher VR maximum current requires upsizing the power train, resulting in high switching losses and lower efficiency. In particular, stacking n transistors to enable high voltage VRs increases the power train loss figure of merit, FOM=Ron*Qg by n\hat{ }2 which results in lower efficiency at the iso-switching frequency, Fsw. Ron denotes the on resistance of the power switch and Qg denotes the charge on the control gate of the power switch.

Switched-capacitor voltage regulators (SCVR) can eliminate the need for inductors, but suffer a trade-off between efficiency and power density since Ploss=(IL\hat{ }2)/(Cf*Fsw)+Pcond+Psw. Ploss denotes the power loss, IL denotes the load current, Cf denotes the capacitance of a flying capacitor, Pcond denotes the conduction power loss and Psw denotes the switching power loss. Currently, for optimized power train size, the only way to increase the SCVR efficiency is by increasing the capacitance, Cf, of the flying capacitors of the VR, which would result in a larger area/lower current density.

The gate switching loss, Pgate=Qg*Vdrv*Fsw, is the dominant VR switching loss that does not scale anymore with process technology. Vdrv is the drive voltage of a voltage source of the VR.

In a non-complementary metal-oxide semiconductor (CMOS) based DC-DC converter, such as a converter using Gallium Nitride (GaN) or laterally-diffused metal-oxide semiconductor (LDMOS), a thick-oxide gate driver CMOS is used. This may be for 1.8 V or 3.3 V devices, for example. This results in high gate switching losses and efficiency degradation. CMOS is a type of metal-oxide semiconductor field-effect transistor fabrication process that uses complementary and symmetrical pairs of p-type and n-type MOSFETs in silicon for logic functions. GaN is a stable, wide bandgap semiconductor which has a higher breakdown strength, faster switching speed, higher thermal conductivity and lower on-resistance than silicon-based devices.

Finding a way to effectively reduce gate loss would help reduce VR switching losses and solve the challenges mentioned above.

Some solutions to reduce switching losses or increasing power density include optimizing device loss parameters such as Qg and/or passive component density such as metal-insulator-metal (MIM)/trench capacitors. Other solutions utilize special devices with excellent FOM such as GaN. The soft-switching technique is one of the traditional solutions used in VR. Other solutions utilize inductors for implementing gate resonance techniques to reduce gate-switching losses.

However, optimizing device loss parameters such as Qg and/or passive component density such as with MIM/trench capacitors relies highly on process technology. Using special devices such as GaN is an expensive solution that is also incompatible with the CMOS process. On the other hand, circuit techniques such as soft-switching can only help reduce drain-switching losses. While using the gate resonance technique can help reduce gate switching losses, the inductor overhead makes it unsuitable for high-power density implementations.

The solutions described herein address the above and other issues. In one aspect, the solution depends on a circuit technique rather than a process/technology level to reduce the effective gate capacitance seen by the driver, hence reducing the gate switching losses. The solution eliminates the need for extra voltage sources by using charge-recycled push-pull capacitors or switched capacitors to efficiently generate multiple voltage levels to charge and discharge the power switch gate in a staircase voltage step fashion rather than a single voltage step using the same rise and fall time. The effective Qg is reduced by a factor of N, where N is the number of voltage steps. N is an integer of two or more. The solution can be applied to any device type and any switching regulator VR type including switched capacitor, buck, hybrid, etc.

The solutions provide a number of advantages including providing a reliable, high frequency, high voltage VR solution with high-power density and eliminating the need for two-stage converters to improve the end-to-end efficiency and reduce the area. By providing a higher voltage VR, this minimizes the input current which greatly reduces the power distribution losses (RLoss) in higher current applications such as servers and graphics processing units (GPU). Pushing the switching frequency higher reduces the die area/cost, decoupling, and inductor size and improves load line performance. In addition, it can facilitate enabling magnetic material-based inductors which can eliminate the inductor footprint on the client platforms that are currently the most dominating area consumers.

In one aspect, a driver for a voltage converter efficiently generates a control gate voltage of a power switch. The driver applies a staircase increasing and decreasing voltage to the control gate with three or more voltage levels, including an initial level such as 0 V, one or more intermediate voltages, and a peak drive voltage. The one or more intermediate voltages can be generated by a charge-recycling circuit which can include push-pull capacitors or switched capacitors. The push-pull capacitors are provided in a number of push-pull regulation circuits which is equal to the number of intermediate voltages. The switched capacitors are provided in a circuit where the number of switched capacitors is equal to the number of intermediate voltages. The one or more intermediate voltages may be positive voltages which are less than the peak drive voltage.

These and other features will be further apparent in view of the following discussion.

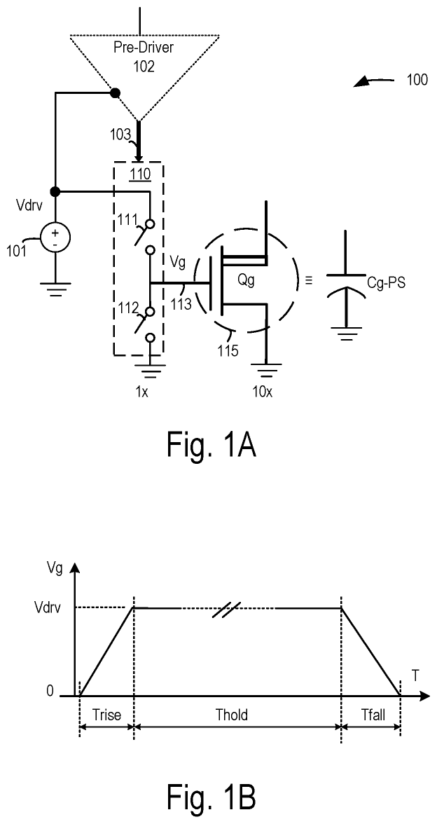

FIG. 1A depicts an example voltage regulator (VR) 100 including a two-level driver 110, in accordance with various embodiments. The VR includes a voltage source 101 which outputs a drive voltage Vdrv to drive a pre-driver 102. An output 103 of the pre-driver is provided to a driver 110, which includes switches 111 and 112 connected serially between the output of the pre-driver and ground. An output path 113 of the driver is connected between the two switches which may be transistors, for example. The output path provides a control gate voltage Vg to a power switch 115 such Is an n-type metal-oxide-semiconductor field-effect transistor (nMOSFET). When the switch 111 is closed (conductive), the switch 112 is open (non-conductive) so that Vg=Vdrv. When the switch 111 is open, the switch 112 is closed so that Vg=0 V. Thus, Vg can have two voltage levels.

The power switch may be an asymmetric MOSFET, for example, where the source and drain regions have different doping levels or are made of different materials. This results in an asymmetrical structure where the transistor has different electrical properties depending on the direction of current flow. Asymmetric MOSFETs can be used to improve efficiency and reduce switching losses. An asymmetric transistor is denoted by a transistor symbol in which one side is thicker than the other. A symmetric transistor is denoted by a transistor symbol in which both sides have the same thickness. Generally, the power switch can be generic. It can be symmetric CMOS or asymmetric LDMOS or GAN.

A capacitor Cg-PS represents a capacitance of the control gate of the power switch (PS). The notation 1× and 10× indicates that the power switch size and gate capacitance can be more than 10× that of the driver.

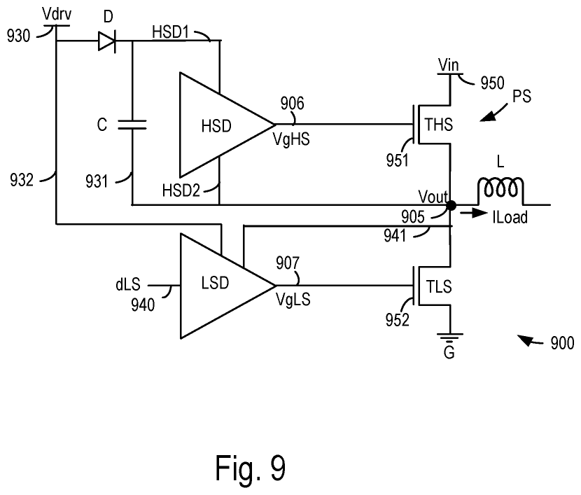

In some cases, a VR includes high-side and low-side power switches which are alternately driven by the driver. See, e.g., FIG. 9.

Generally, an N-level driver provides a control gate voltage Vg of a power switch with N voltage steps and N+1 total voltage levels. N is an integer ≥2. In some cases, N≥3 or higher.

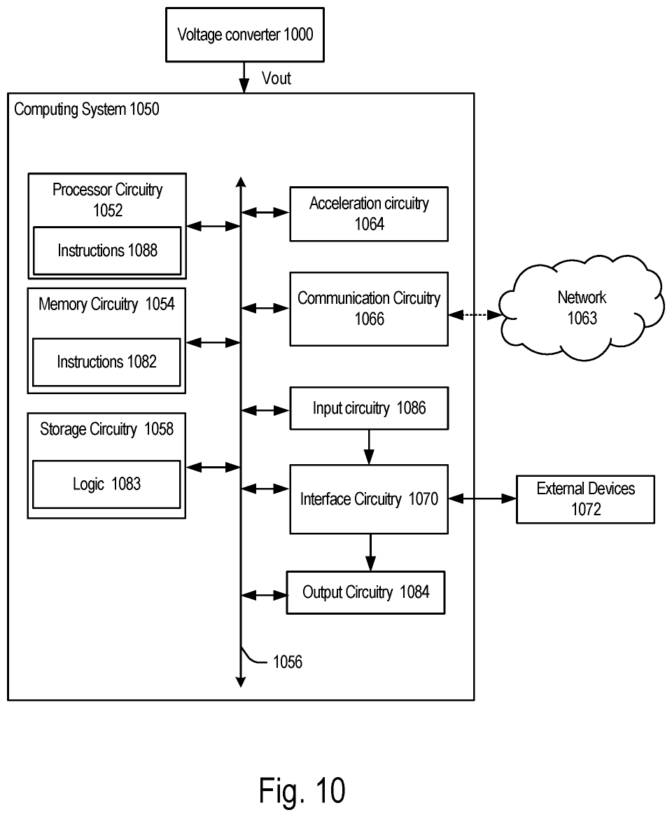

Control signals can be provided from a control circuit to control the switches. An example control circuit is the processor circuitry 1052 of FIG. 10.

FIG. 1B depicts an example plot of the output voltage Vg versus time for the driver of FIG. 1A, in accordance with various embodiments. In a drive cycle, Vg is increased from 0 V (or other initial level) to a peak level such as 1 V in a rise time period, Trise, held at its peak level Vdrv for a hold period of time, Thold, then decreased from Vdrv to 0 V (or other initial level) in a fall period of time, Tfall. The drive power of the driver is: Pdrv=Cg*ΔVdrv\vec{ }2*Fsw=Cg*Vdrv\hat{ }2*Fsw=Qg*Vdrv*Fsw.

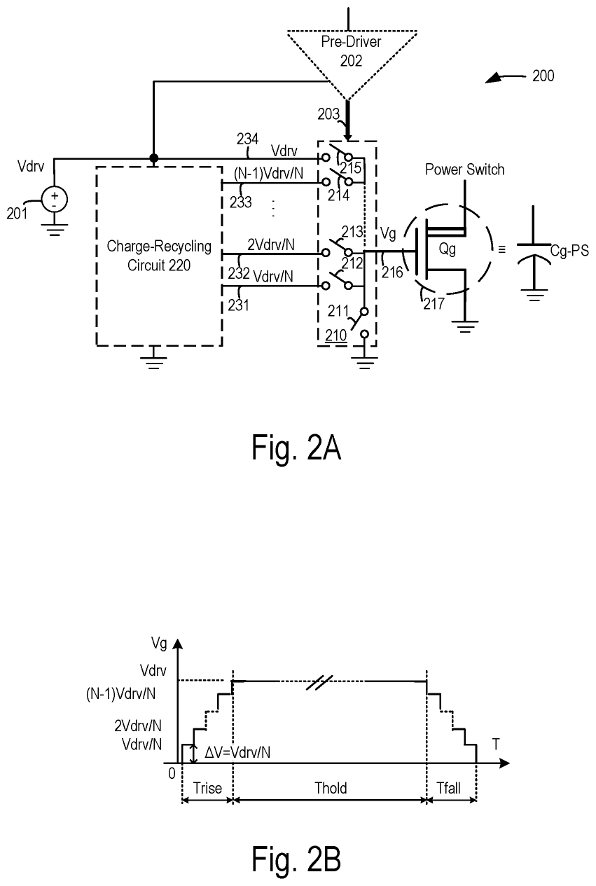

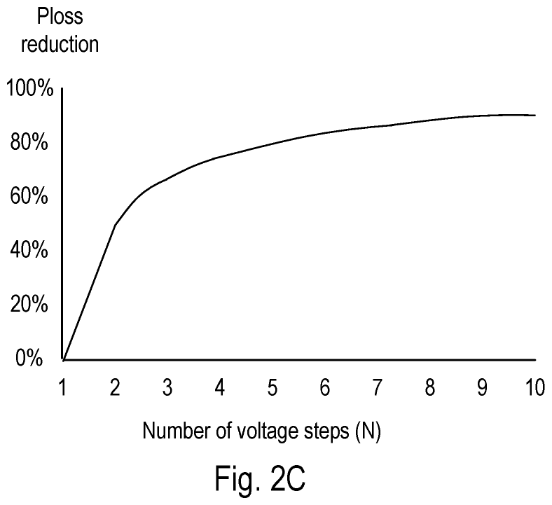

FIG. 2A depicts an example VR 200 including a multi-level driver 210 with a charge-recycling circuit 220, in accordance with various embodiments. The VR includes a voltage source 201 which outputs a drive voltage Vdrv to drive a pre-driver 202 and the charge-recycling circuit 220. An output 203 of the pre-driver is provided to a driver 210, which includes a set of switches 211-215 connected serially between the output of the pre-driver and ground. An output path 216 of the driver is connected to the switches. The output path provides Vg to a power switch 217.

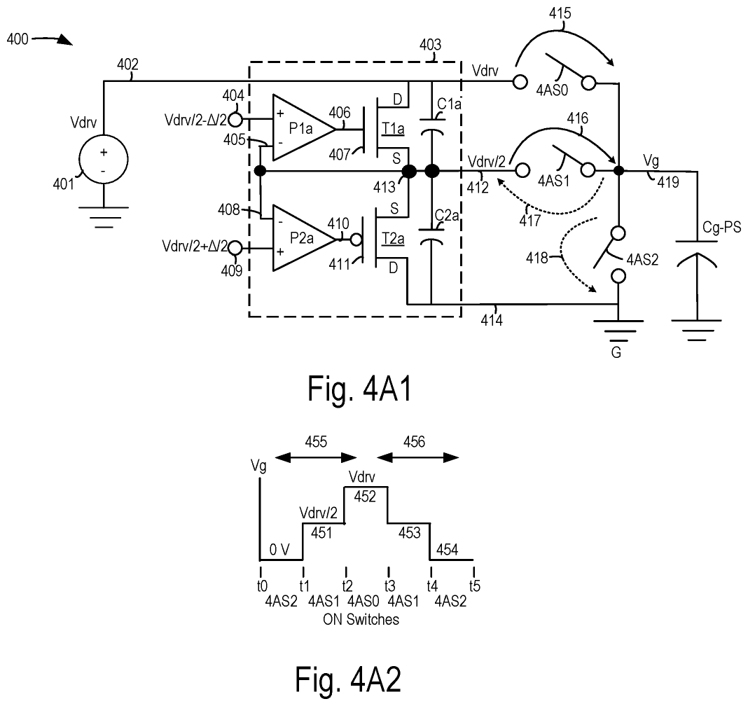

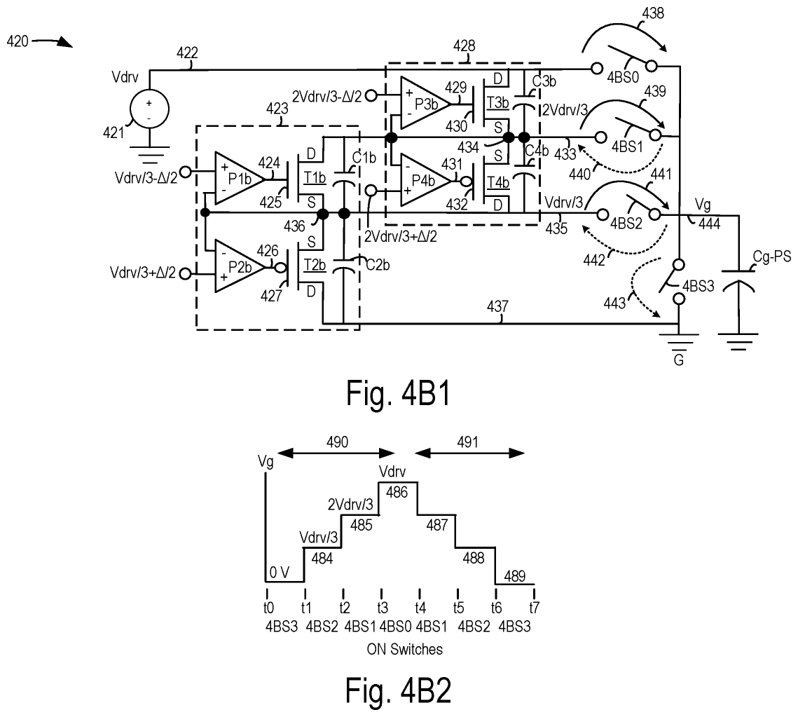

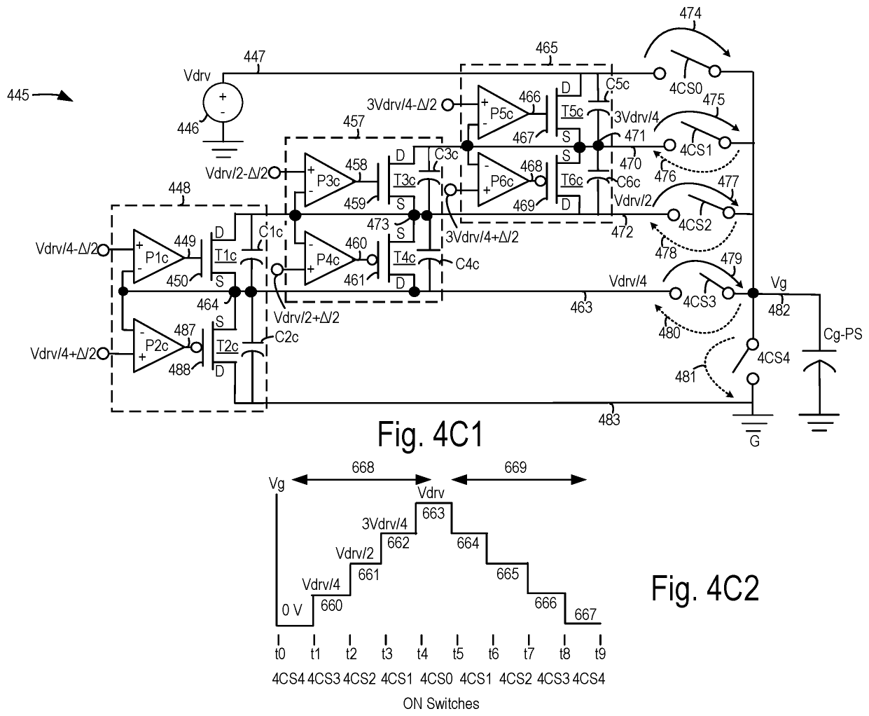

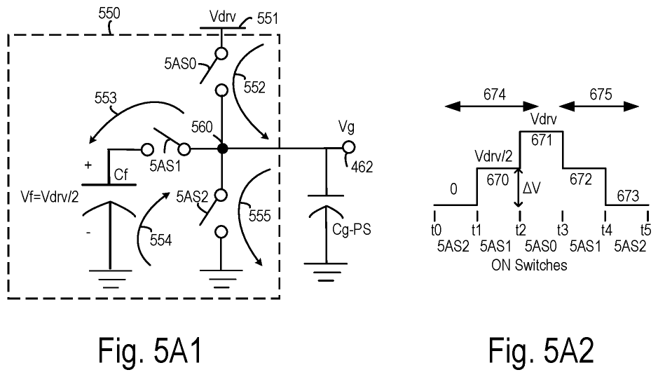

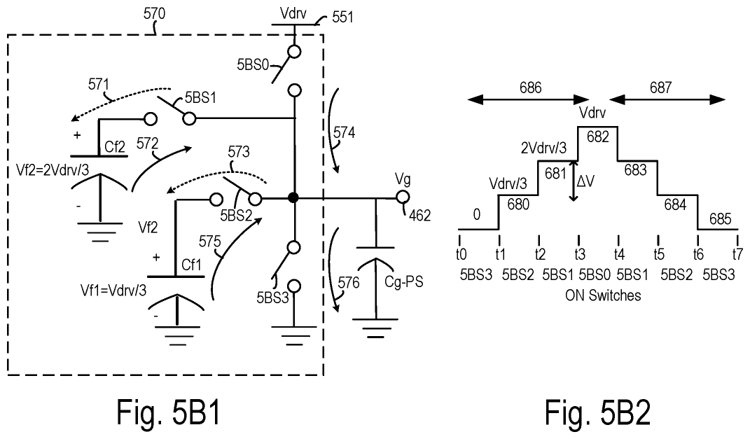

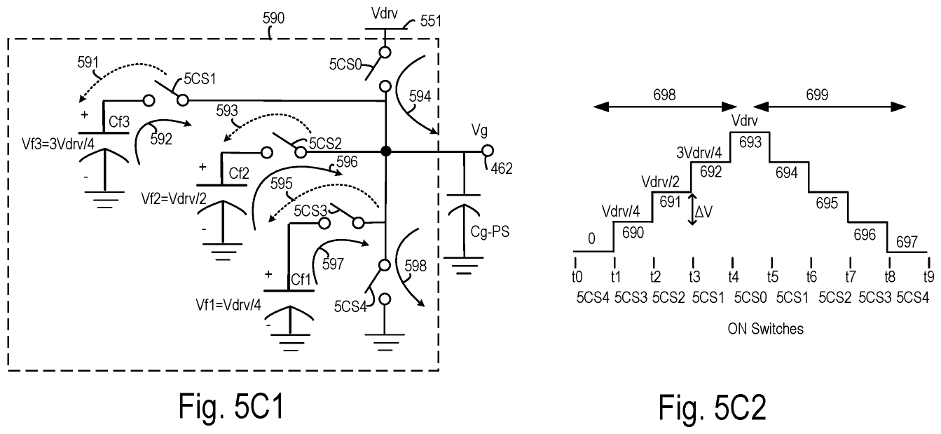

The charge-recycling circuit 220 can represent, e.g., a push-pull capacitor circuit (see, e.g., FIG. 4A1-4C2) or a switched capacitor circuit (see, e.g., FIG. 5A1-5C2). The circuit provides output voltages Vdrv/N, 2Vdrv/N, . . . , (N−1) Vdrv/N on paths 231, 232, . . . , 233 to switches 212, 213, . . . , 214. Vdrv is provided to the switch 215 on the path 234. Thus, the driver receives N voltages which are separated by equal increments or steps, in this example. In another approach, the N voltages can be separated by one or more unequal increments or steps. For example, with N=4, one-fourth of Vdrv is provided on the path 231 to the switch 212, one-half of Vdrv is provided on the path 232 to the switch 213, three-fourths of Vdrv is provided on the path 233 to the switch 214, and Vdrv is provided on the path 234 to the switch 215. The switch 211 can be used to couple the driver to ground.

During a drive cycle, one voltage at a time is passed from the driver to the output path 216 as Vg, thus forming a staircase waveform for Vg. The waveform includes an increasing staircase to increase Vg and a decreasing staircase to decrease Vg. For example, when the switches 211 and 213-215 are off, and the switch 212 is on, Vdrv/N is passed to the output path 216. When the switches 211, 212, 214 and 215 are off, and the switch 213 is on, 2Vdrv/N is passed to the output path 216. When the switches 211-213 and 215 are off, and the switch 214 is on, (N−1) Vdrv/N is passed to the output path 216. When the switches 211-214 are off, and the switch 215 is on, Vdrv is passed to the output path 216. When the switches 211-215 are off, and the switch 211 is on, the output path 216 is grounded.

Generally, turning on and off the power switch in multi-level voltage steps reduces the gate switching losses by a factor of N. In the charge-recycling circuit 220, charge-recycled low-dropout (LDO) capacitors or switched capacitors can be used to generate the multi-level voltage steps efficiently and minimize the overhead.

The reduction of power consumption can be seen as follows. Pdrv=Cg*ΔVdrv\hat{ }2*Fsw=N*Cg*(Vdrv/N)\hat{ }2*Fsw=Cg*(Vdrv\hat{ }2/N)*Fsw=Qg*Vdrv*Fsw/N. Thus, compared to the VR of FIG. 1A, Pdrv is reduced by a factor of N. The reduction in power consumption is therefore greater when N is greater.

FIG. 2B depicts an example plot of the output voltage Vg versus time for the driver of FIG. 2A, in accordance with various embodiments. The output voltage forms a waveform having an increasing staircase shape and a decreasing staircase shape. In a drive cycle, Vg is increased from 0 V (or other initial level) to a peak level Vdrv in N steps in a rise time period, Trise, held at its peak level Vdrv for a hold period of time, Thold, then decreased from Vdrv to 0 V (or other initial level) in N steps in a fall period of time, Tfall. The increasing steps are denoted by Vdrv/N, 2Vdrv/N, . . . , (N−1) Vdrv/N and Vdrv and the decreasing steps are denoted by Vdrv, (N−1) Vdrv/N, 2Vdrv/N, . . . , Vdrv/N and 0 V.

FIG. 2C depicts an example plot of gate switching loss (Ploss) reduction versus number of voltage steps (N) for the driver of FIG. 2A, in accordance with various embodiments. The Ploss reduction increases as N increases but at a reduced rate, for example, from 50%, at N=2 to 90.0% at N=10. Although, the complexity and size of the VR can also increase as N increases. An optimum N can be selected based on the design considerations of the VR. Ploss refers to the difference between the input power and the output power of the VR. The main function of the VR is to regulate voltage and generate current. Ploss can include a switching loss, Psw, and a conduction loss, Pcond, among other losses. Psw is typically the largest loss, and can be defined as Psw=C*Vdrv\hat{ }2*Fsw. Ideally, Ploss=0 for 100% efficiency, where the efficiency is Pout/Pin. Fsw is the frequency of switching cycles of a power switch. The control gate voltage of the power switch is charged up to a peak and then discharged, e.g., to 0 V in each cycle. Fsw can be defined as the frequency at which the peak voltages are reached.

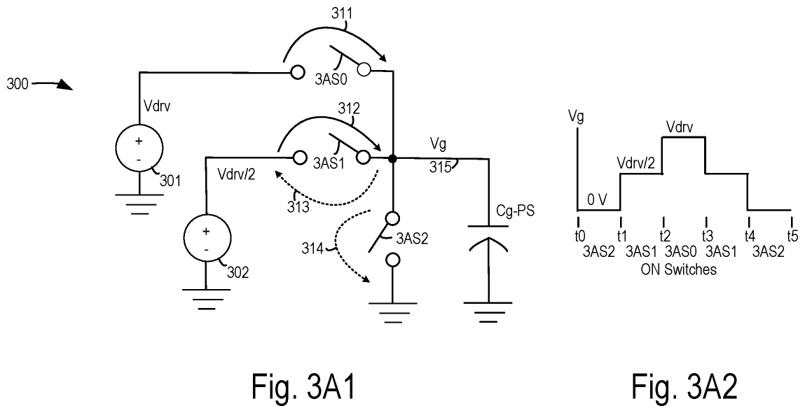

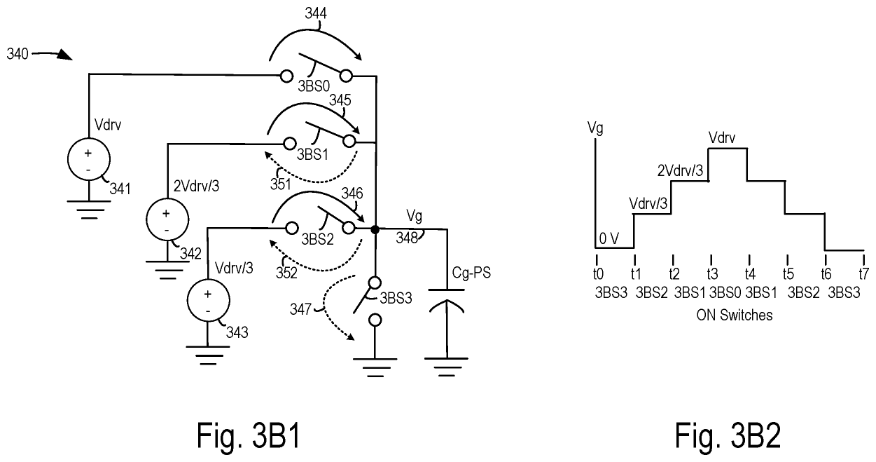

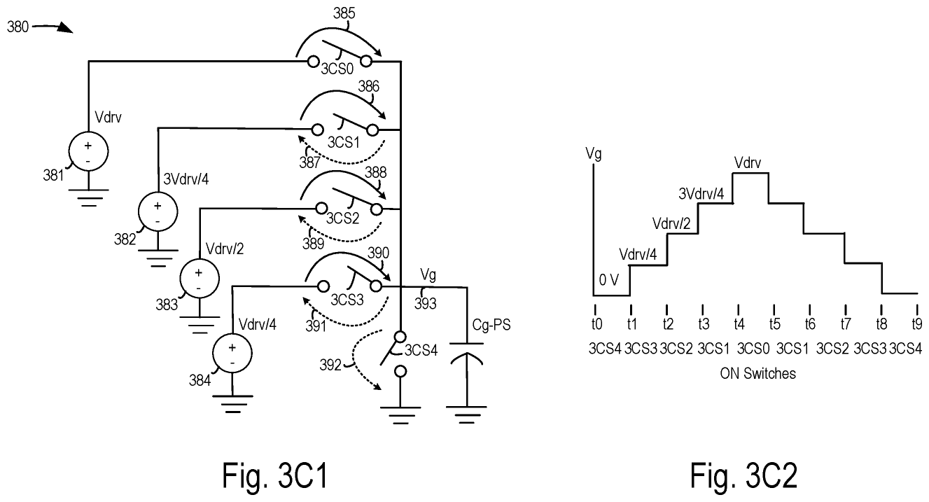

Generally, driving the control gate of the power switch with a staircase waveform reduces the gate driver switching losses by 1/N. Although, the use of extra voltage sources required to provide the different voltage levels, such as discussed in connection with FIG. 3A1-3C2, can be impractical. The solutions provided herein include two approaches for generating multiple voltage levels which avoid the need for additional external voltage sources. A first approach involves push-pull charge recycled rail generation and regulation, such as discussed in connection with FIG. 4A1-4C2. A second approach involves multi-level switched capacitors, such as discussed in connection with FIG. 5A1-5C2.

FIG. 3A1 depicts an example three-level driver 300 with two voltage sources, in accordance with various embodiments. A first voltage source 301 outputs Vdrv to a switch 3AS0 and a second voltage source 302 outputs Vdrv/2 to a switch 3AS1. An output path 315 at Vg receives 0 V when a switch 3AS2 is closed and the switches 3AS0 and 3AS1 are open, Vdrv/2 when the switch 3AS1 is closed and the switches 3AS0 and 3AS2 are open, and Vdrv when the switch 3AS0 is closed and the switches 3AS1 and 3AS2 are open. The second voltage source is one extra voltage source which is provided to generate the intermediate voltage Vdrv/2. An intermediate voltage is a step voltage of Vg which is between the minimum (e.g., 0 V) and maximum (e.g., Vdrv) voltages.

The output path is coupled to Cg-PS. Due to the capacitance, charge recycling can occur in which charge is transferred from the voltage sources to the capacitor and back from the capacitor to the voltage sources. For example, the arrow 312 represents charge being transferred from the voltage source 302 to the capacitor via the switch 3AS1 at t1 in FIG. 3A2. The arrow 311 represents charge being transferred from the voltage source 301 to the capacitor via the switch 3AS0 at t2 in FIG. 3A2.

The arrow 313 represents charge being transferred from the capacitor to the voltage source 302 via the switch 3AS1 at t3 in FIG. 3A2. The arrow 314 represents charge being transferred from the capacitor to ground via the switch 3AS2 at t4 in FIG. 3A2.

With N=2, the power consumption in this example is Pdrv=Qg*Vdrv*Fsw/2.

This approach requires multiple external voltage sources to generate different voltage levels to achieve the goal of reducing gate switching loss. However, this may be not desirable due to the large overhead costs. Although, charging and discharging from/to the same extra voltage sources recycles the energy instead of dumping it to ground. Charge recycling from the extra voltage sources results in no energy loss but voltage regulation is still required.

FIG. 3A2 depicts an example plot of the output voltage Vg versus time for the driver of FIG. 3A1, in accordance with various embodiments. In FIGS. 3A2, 3B2, 3C2, 4A2, 4B2 4C2, 5A2, 5B2 and 5C2, the horizontal axis denotes the switch which is on in different time intervals. These figures show a charge-discharge cycle of the control gate, in which one switch at a time is closed while the others are open. N=2 since there are two voltage steps. For example, starting from 0 V from t0-t1 with 3AS2 closed, there is a voltage step up to Vdrv/2 at t1-t2 with 3AS1 closed and a voltage step up from Vdrv/2 to Vdrv at t2-t3 with 3AS0 closed. Starting from Vdrv, there is a voltage step down to Vdrv/2 at t3-t4 with 3AS1 closed and a voltage step down from Vdrv/2 to 0 V at t4-t5 with 3AS2 closed.

FIG. 3B1 depicts an example four-level driver 340 with three voltage sources, in accordance with various embodiments. A first voltage source 341 outputs Vdrv to a switch 3BS0, a second voltage source 342 outputs 2Vdrv/3 to a switch 3BS1, and a third voltage source 343 outputs Vdrv/3 to a switch 3BS2. An output path 348 at Vg receives 0 V when a switch 3BS3 is closed and the switches 3BS0-3BS2 are open, Vdrv/3 when the switch 3BS2 is closed and the switches 3BS0, 3BS1 and 3BS3 are open, 2Vdrv/3 when the switch 3BS1 is closed and the switches 3BS0, 3BS2 and 3BS3 are open, and Vdrv when the switch 3BS0 is closed and the switches 3BS1-3BS3 are open. The second and third voltage sources are two extra voltage sources which are provided to generate the intermediate voltages 2Vdrv/3 and Vdrv/3, respectively.

The output path is coupled to a capacitor Cg-PS. As before, charge recycling can occur. For example, the arrow 346 represents charge being transferred from the voltage source 343 to the capacitor via the switch 3BS2 at t1 in FIG. 3B2. The arrow 345 represents charge being transferred from the voltage source 342 to the capacitor via the switch 3BS1 at t2 in FIG. 3B2. The arrow 344 represents charge being transferred from the voltage source 341 to the capacitor via the switch 3BS0 at t3 in FIG. 3B2.

The arrow 351 represents charge being transferred from the capacitor to the voltage source 342 via the switch 3BS1 at t4 in FIG. 3B2. The arrow 352 represents charge being transferred from the capacitor to the voltage source 343 via the switch 3BS2 at t5 in FIG. 3B2. The arrow 347 represents charge being transferred from the capacitor to ground via the switch 3BS3 at t6 in FIG. 3B2.

With N=3, the power consumption in this example is Pdrv=Qg*Vdrv*Fsw/3.

FIG. 3B2 depicts an example plot of the output voltage Vg versus time for the driver of FIG. 3B1, in accordance with various embodiments. N=3 since there are three voltage steps. For example, starting from 0 V from t0-t1 with 3BS3 closed, there is a voltage step up to Vdrv/3 at t1-t2 with 3BS2 on, a voltage step up from Vdrv/3 to 2Vdrv/3 at t2-t3 with 3BS1 closed, and a voltage step up from 2Vdrv/3 to Vdrv at t3-t4 with 3BS0 closed. Starting from Vdrv, there is a voltage step down to 2Vdrv/3 at t4-t5 with 3BS1 closed, a voltage step down from 2Vdrv/3 to Vdrv/3 at t5-t6 with 3BS2 closed, and a voltage step down from Vdrv/3 to 0 V at t6-t7 with 3BS3 closed.

FIG. 3C1 depicts an example five-level driver 380 with four voltage sources, in accordance with various embodiments. A first voltage source 381 outputs Vdrv to a switch 3CS0, a second voltage source 382 outputs 3Vdrv/4 to a switch 3CS1, a third voltage source 383 outputs Vdrv/2 to a switch 3CS2, and a fourth voltage source 384 outputs Vdrv/4 to a switch 3CS3. An output path 393 at Vg receives 0 V when a switch 3CS4 is closed and the switches 3CS0-3CS3 are open, Vdrv/4 when the switch 3CS3 is closed and the switches 3CS0-3CS2 and 3CS4 are open, Vdrv/2 when the switch 3CS2 is closed and the switches 3CS0, 3CS1, 3CS3 and 3CS4 are open, 3Vdrv/4 when the switch 3CS1 is closed and the switches 3CS0 and 3CS2-3CS4 are open, and Vdrv when the switch 3CS0 is closed and the switches 3CS1-3CS4 are open. The second-fourth voltage sources are three extra voltage sources which are provided to generate the intermediate voltages 3Vdrv/4, Vdrv/2 and Vdrv/4, respectively.

The output path is coupled to Cg-PS. As before, charge recycling can occur. For example, the arrow 390 represents charge being transferred from the voltage source 384 to the capacitor via the switch 3CS3 at t1 in FIG. 3C2. The arrow 388 represents charge being transferred from the voltage source 383 to the capacitor via the switch 3CS2 at t2 in FIG. 3C2. The arrow 386 represents charge being transferred from the voltage source 382 to the capacitor via the switch 3CS1 at t3 in FIG. 3C2. The arrow 385 represents charge being transferred from the voltage source 381 to the capacitor via the switch 3CS0 at t4 in FIG. 3C2.

The arrow 387 represents charge being transferred from the capacitor to the voltage source 382 via the switch 3CS1 at t5 in FIG. 3C2. The arrow 389 represents charge being transferred from the capacitor to the voltage source 383 via the switch 3CS2 at t6 in FIG. 3C2. The arrow 391 represents charge being transferred from the capacitor to the voltage source 384 via the switch 3CS3 at t7 in FIG. 3C2. The arrow 392 represents charge being transferred from the capacitor to ground via the switch 3CS4 at t8 in FIG. 3C2.

With N=4, the power consumption in this example is Pdrv=Qg*Vdrv*Fsw/4.

FIG. 3C2 depicts an example plot of the output voltage Vg versus time for the driver of FIG. 3C1, in accordance with various embodiments. N=4 since there are four voltage steps. For example, starting from 0 V from t0-t1 with 3CS4 closed, there is a voltage step up to Vdrv/4 at t1-t2 with 3CS3 closed, a voltage step up from Vdrv/4 to Vdrv/2 at t2-t3 with 3CS2 closed, a voltage step up from Vdrv/2 to 3Vdrv/4 at t3-t4 with 3CS1 closed, and a voltage step up from 3Vdrv/4 to Vdrv at t4-t5 with 3CS0 closed. Starting from Vdrv, there is a voltage step down to 3Vdrv/4 at t5-t6 with 3CS1 closed, a voltage step down from 3Vdrv/4 to Vdrv/2 at t6-t7 with 3CS2 closed, a voltage step down from Vdrv/2 to Vdrv/4 at t7-t8 with 3CS3 closed, and a voltage step down from Vdrv/4 to 0 V at t8-t9 with 3CS4 closed.

FIGS. 3A1, 3B1 and 3C1 require one or more extra voltage sources to generate one or more intermediate voltages, which results in a large overhead cost.

FIG. 4A1 depicts an example three-level driver 400 with digital push-pull regulation for charge recycling, consistent with the charge-recycling circuit 220 of FIG. 2A, in accordance with various embodiments. A voltage source 401 outputs Vdrv to a switch 4AS0 via a supply path 402. A push-pull regulation circuit 403 includes a first comparator P1a to provide a voltage on an output path 406 to a control gate 407 of a first transistor T1a (an nMOSFET in this example, as shown by a control gate without a circle) and a second comparator P2a to provide a voltage on an output path 410 to a control gate 411 of a second transistor T2a (a p-type MOSFET or pMOSFET in this example, as shown by a control gate with a circle). T1a and T2a are a pair of push-pull transistors. The first and second transistors are coupled in series between the supply path 402 and a ground path 414. The push-pull regulation circuit provides Vdrv/2 at a node 413 of the path 412 which is between, and in series with, the transistors, and to a switch 4AS1 via the path 412. Vg at an output path 419 is Vdrv when the switch 4AS0 is closed and the switches 4AS1 and 4AS2 are open, Vdrv/2 when the switch 4AS1 is closed and the switches 4AS0 and 4AS2 are open, and 0 V when the switch 4AS2 is closed and the switches 4AS0 and 4AS1 are open.

The first and second comparators regulate the voltage at the path 412 (a first regulated path) to Vdrv/2+/−Δ/2 so that there is a hysteresis window of width A centered at Vdrv/2. Δ/2 can be considered to be half of a hysteresis window or margin. To achieve this, the first comparator receives Vdrv/2−Δ/2 at a non-inverting input 404 and the regulated voltage at the path 412 at an inverting input 405. Vdrv/2 is a reference voltage. Additionally, the second comparator receives Vdrv/2+Δ/2 at a non-inverting input 409 and the regulated voltage at the path 412 at an inverting input 408. The output path 406 goes high (e.g., to a voltage which is sufficiently high to turn on the nMOSFET) to turn on the first transistor and thereby increase the voltage at the path 412 when the regulated voltage falls below Vdrv/2−Δ/2. The output path 410 goes low (e.g., to a voltage which is sufficiently low to turn on the pMOSFET) to turn on the second transistor and thereby decrease the voltage at the path 412 when the regulated voltage increases above Vdrv/2+Δ/2. This is referred to as push-pull regulation of the path 412.

Generally, the non-inverting input of the first comparator can be set to a reference voltage minus a hysteresis increment, and the non-inverting input of the second comparator can be set to the reference voltage plus a hysteresis increment. For example, if Vdrv/2=0.5 V, with an example increment of 0.05 V, Vdrv/2 is regulated to a range of 0.45-0.55 V. The hysteresis window is 0.1 V.

A first capacitor C1a is coupled to the supply path 402 and a path 412 and stores a charge of Vdrv/2. A second capacitor C2a is coupled to the path 414 and the path 412 and also stores a charge of Vdrv/2. The first transistor is coupled at its drain (D) to the supply path 402 and at its source (S) to the path 412. The second transistor is coupled at its source to the path 412 and at its drain to the path 414. The first capacitor is thus coupled in parallel with the first transistor, between the supply path 402 which is coupled to the voltage source and the path 412 which is coupled between the first and second transistors, and the second capacitor is coupled in parallel with the second transistor, between the path 412 and a ground node G.

The capacitors can transfer charge to, and receive charge from, Cg-PS. The capacitors C1a and C2s are push-pull capacitors since they push current to, and pull current from, Cg-PS, in each charge-discharge cycle. The current is pushed to Cg-PS during a charge phase of the charge-discharge cycle and pulled from Cg-PS during a discharge phase of the charge-discharge cycle.

For example, the arrow 416 represents charge being transferred from C2a to Cg-PS via the switch 4AS1 at t1 in FIG. 4A2, and the arrow 417 represents charge being transferred in the opposite direction, to C2a from Cg-PS via the switch 4AS1 at t3 in FIG. 4A2. The arrow 415 represents charge being transferred from the voltage source 401 to Cg-PS via the switch 4AS0 at t2 in FIG. 4A2. The arrow 418 represents charge being transferred to a ground node G from Cg-PS via the switch 4AS2 at t4 in FIG. 4A2.

The number of push-pull regulation circuits can be equal to the number of intermediate voltages, which is N−1. The number of voltage levels including 0 V, Vdrv and the one or more intermediate voltages is N+1. In a charge cycle, the number of increasing voltage steps is N in a charge phase and the number of decreasing voltage steps is N in a discharge phase. N=2 in this example.

The push-pull regulation circuit 403 includes two capacitors coupled serially. The capacitor coupled to ground, C2a, is used to transfer charge to, and receive charge from, Cg-PS.

Generally, FIG. 4A1 depicts a charge-recycled push-pull rail generation and regulation concept for a multi-level driver. Push-pull rail generation eliminates the need for extra voltage sources. The push-pull regulation circuit 403 includes an nMOSFET to push current, a pMOSFET to pull current, and comparators. The generated rails are regulated within a hysteresis window, Δ, by turning ON and OFF the push-pull nMOSFET and pMOSFET. If the generated voltage exceeds the reference voltage by ΔV, the comparator triggers the turn ON of the nMOSFET to push in the current t the node 413. If the generated voltage drops below the reference voltage by Δ/2, the comparator triggers the turn ON of the pMOSFET to pull out the current from the node 413. If the generated voltage is within the hysteresis window, the nMOSFET and pMOSFET are off. Since the net output current of the push-pull module is zero amps, there is no resistive loss.

FIG. 4A2 depicts an example plot of the output voltage Vg versus time for the driver of FIG. 4A1, in accordance with various embodiments. N=2 since there are two voltage steps. For example, starting from 0 V from t0-t1 with 4AS2 closed, there is a first voltage step up to Vdrv/2 at t1-t2 with 4AS1 closed, and a second voltage step up from Vdrv/2 to Vdrv at t2-t3 with 4AS0 closed. Starting from Vdrv, there is a first voltage step down to Vdrv/2 at t3-t4 with 4AS1 closed, and a second voltage step down from Vdrv/to 0 V at t4-t5 with 4AS2 closed.

The charge-discharge cycle includes a charge phase from t0-t2 and a discharge phase from t3-t5.

The figure depicts increasing voltage steps 451 and 452 in a charge phase 455 and decreasing voltage steps 453 and 454 in a discharge phase 456.

Vdrv/2 may be considered to be a first intermediate voltage.

FIG. 4B1 depicts an example four-level driver 420 with digital push-pull regulation for charge recycling, consistent with the charge-recycling circuit 220 of FIG. 2A, in accordance with various embodiments. A voltage source 421 outputs Vdrv to a switch 4BS0 via a path 422. A first push-pull regulation circuit 423 includes a first comparator P1b to provide a voltage on an output path 424 to a control gate 425 of a first transistor T1b and a second comparator P2b to provide a voltage on an output path 426 to a control gate 427 of a second transistor T2b. The first and second transistors are coupled in series between a path 433 and a ground path 437. The first push-pull regulation circuit provides Vdrv/3 at a node 436 of the path 435 which is between, and in series with, the transistors T1b and T2b, and to a switch 4BS2 via the path 435.

A second push-pull regulation circuit 428 includes a first comparator P3b to provide a voltage on an output path 429 to a control gate 430 of a third transistor T3b and a second comparator P4b to provide a voltage on an output path 431 to a control gate 432 of a fourth transistor T4b. The third and fourth transistors are coupled in series between the paths 422 and 435. The second push-pull regulation circuit provides 2Vdrv/3 at a node 434 of the path 433 which is between, and in series with, the transistors T3b and T4b, and to a switch 4BS1 via the path 433. 4BS2 may be a first switch and 4BS1 may be an additional switch.

In this case, multiple push-pull regulation circuits are provided, one push-pull regulation circuit for each intermediate voltage of Vg.

Vg at an output path 444 is Vdrv when the switch 4BS0 is closed and the switches 4BS1-4BS3 are open, 2Vdrv/3 when the switch 4BS1 is closed and the switches 4BS0, 4BS2 and 4BS3 are open, Vdrv/3 when the switch 4BS2 is closed and the switches 4BS0, 4BS1 and 4BS3 are open, and 0 V when the switch 4BS3 is closed and the switches 4BS0-4BS2 are open.

In the first push-pull regulation circuit 423, the first and second comparators regulate the voltage at the path 435 (a first regulated path) to Vdrv/3+/−Δ/2 so that there is a hysteresis window of width A centered at Vdrv/3. Vdrv/3 is a reference voltage. Note that the hysteresis window is the same for each intermediate step voltage in this example but could be different for different intermediate step voltages. To achieve the regulation, the first comparator P1b receives Vdrv/3−Δ/2 at a non-inverting input (+) and the regulated voltage at the path 435 at an inverting input (−). Additionally, the second comparator P2b receives Vdrv/3+Δ/2 at a non-inverting input and the regulated voltage at the path 435 at an inverting input. The output path 424 goes high to turn on the first transistor T1b and thereby increase the voltage at the path 435 when the regulated voltage falls below Vdrv/3−Δ/2. The output path 426 goes low to turn on the second transistor T2b and thereby decrease the voltage at the path 435 when the regulated voltage increases above Vdrv/3+Δ/2. This is referred to as push-pull regulation of the path 435.

A capacitor C1b is coupled to the paths 433 and 435 and stores a charge of Vdrv/3. A capacitor C2b is coupled to the paths 435 and 437 and also stores a charge of Vdrv/3. T1b is coupled at its drain to the path 433 and at its source to the path 435. T2b is coupled at its source to the path 435 and at its drain to the path 437. C2b can transfer charge to, and receive charge from, Cg-PS. For example, the arrow 441 represents charge being transferred from C2b to Cg-PS via the switch 4BS2 at t1 in FIG. 4B2, and the arrow 442 represents charge being transferred in the opposite direction, from Cg-PS to C2b at t5 in FIG. 4B2.

In the second push-pull regulation circuit 428, the third and fourth comparators regulate the voltage at the path 433 (a second regulated path) to 2Vdrv/3+/−Δ/2 so that there is a hysteresis window of width A centered at 2Vdrv/3. To achieve this, the third comparator P3b receives 2Vdrv/3−Δ/2 at a non-inverting input (+) and the regulated voltage at the path 433 at an inverting input (−). 2Vdrv/3 is a reference voltage. Additionally, the fourth comparator P4b receives 2Vdrv/3+Δ/2 at a non-inverting input and the regulated voltage at the path 433 at an inverting input. The output path 429 goes high to turn on the third transistor T3b and thereby increase the voltage at the path 433 when the regulated voltage falls below 2Vdrv/3−Δ/2. The output path 431 goes low to turn on the fourth transistor T4b and thereby decrease the voltage at the path 433 when the regulated voltage increases above 2Vdrv/3+Δ/2.

A capacitor C3b is coupled to the path 422 and the path 433 and stores a charge of Vdrv/3. A capacitor C4b is coupled to the path 435 and the path 433 and also stores a charge of Vdrv/3. T3b is coupled at its drain to the path 422 and at its source to the node 434. T4b is coupled at its source to the node 434 and at its drain to the path 435. C4b can transfer charge to, and receive charge from, Cg-PS. For example, the arrow 439 represents charge being transferred from C4b to Cg-PS via the switch 4BS1 at t2 in FIG. 4B2, and the arrow 440 represents charge being transferred in the opposite direction, from Cg-PS to C4b at t4 in FIG. 4B2.

The arrow 438 represents charge being transferred from the voltage source 421 to Cg-PS via the switch 4BS0 at t3 in FIG. 4B2. The arrow 443 represents charge being transferred from Cg-PS to ground via the switch 4BS3 at t6 in FIG. 4B2.

FIG. 4B2 depicts an example plot of the output voltage Vg versus time for the driver of FIG. 4B1, in accordance with various embodiments. N=3 since there are three voltage steps. For example, starting from 0 V from t0-t1 with 4BS3 on, there is a first voltage step up to Vdrv/3 at t1-t2 with 4BS2 closed, a second voltage step up from Vdrv/3 to 2Vdrv/3 at t2-t3 with 4BS1 closed, and a third voltage step up from 2Vdrv/3 to Vdrv at t3-t4 with 4BS0 closed. Starting from Vdrv, there is a first voltage step down to 2Vdrv/3 at t4-t5 with 4BS1 closed, a second voltage step down from 2Vdrv/3 to Vdrv/3 at t5-t6 with 4BS2 closed, and a third voltage step down from Vdrv/3 to 0 V at t6-t7 with 4BS3 closed.

The charge-discharge cycle includes a charge phase from t0-t3 and a discharge phase from t4-t7.

The figure depicts increasing voltage steps 484-486 in a charge phase 490 and decreasing voltage steps 487-489 in a discharge phase 491.

Vdrv/3 and 2Vdrv/3 may be considered to be first and second intermediate voltages, respectively.

In this example, first, second and third switches and an additional switch of the driver 420 are capable of providing N=3 increasing voltage steps followed by N=3 decreasing voltage steps on the output path in a charge-discharge cycle of the control gate.

FIG. 4C1 depicts an example five-level driver 445 with digital push-pull regulation for charge recycling, consistent with the charge-recycling circuit 220 of FIG. 2A, in accordance with various embodiments. A voltage source 446 outputs Vdrv to a switch 4CS0 via a path 447. A first push-pull regulation circuit 448 includes a first comparator Plc to provide a voltage on an output path 449 to a control gate 450 of a first transistor T1c and a second comparator P2c to provide a voltage on an output path 487 to a control gate 488 of a second transistor T2c. The first and second transistors are coupled in series between the path 472 and a ground path 483. The first push-pull regulation circuit provides Vdrv/4 at a node 464 of the path 463 which is between, and in series with, the transistors T1c and T2c, and to a switch 4CS3 via the path 463.

A second push-pull regulation circuit 457 includes a third comparator P3c to provide a voltage on an output path 458 to a control gate 459 of a third transistor T3c and a fourth comparator P4c to provide a voltage on an output path 460 to a control gate 461 of a fourth transistor T4c. The third and fourth transistors are coupled in series between paths 470 and 463. The second push-pull regulation circuit provides Vdrv/2 at a node 473 of the path 472 which is between, and in series with, the transistors T3c and T4c, and to a switch 4CS2 via the path 472.

A third push-pull regulation circuit 465 includes a fifth comparator P5c to provide a voltage on an output path 466 to a control gate 467 of a fifth transistor T5c and a sixth comparator P6c to provide a voltage on an output path 468 to a control gate 469 of a sixth transistor T6c. The fifth and sixth transistors are coupled in series between the paths 447 and 472. The third push-pull regulation circuit provides 3Vdrv/4 at a node 471 of the path 470 which is between, and in series with, the transistors T5c and T6c, and to a switch 4CS1 via the path 470. 4CS3 may be a first switch, 4CS2 may be a first additional switch, and 4CS1 may be a second additional switch.

Vg at an output path 482 is Vdrv when the switch 4CS0 is closed and the switches 4CS1-4CS4 are open (charge flows per the arrow 474), 3Vdrv/4 when the switch 4CS1 is closed and the switches 4CS0 and 4CS2-4CS4 are open, Vdrv/2 when the switch 4CS2 is closed and the switches 4CS0, 4CS1, 4CS3 and 4CS4 are open, Vdrv/4 when the switch 4CS3 is closed and the switches 4CS0-4CS2 and 4CS4 are open, and 0 V when the switch 4CS4 is closed and the switches 4CS0-4CS3 are open.

In the first push-pull regulation circuit 448, the first and second comparators regulate the voltage at the path 463 (a first regulated path) to Vdrv/4+/−Δ/2 so that there is a hysteresis window of width A centered at Vdrv/4. To achieve this, the first comparator P1c receives Vdrv/4−Δ/2 at a non-inverting input (+) and the regulated voltage at the path 463 at an inverting input (−). Vdrv/4 is a reference voltage. Additionally, the second comparator P2c receives Vdrv/4+Δ/2 at a non-inverting input and the regulated voltage at the path 463 at an inverting input. The output path 449 goes high to turn on T1c and thereby increase the voltage at the path 463 when the regulated voltage falls below Vdrv/4−Δ/2. The output path 487 goes low to turn on T2c and thereby decrease the voltage at the path 463 when the regulated voltage increases above Vdrv/4+Δ/2.

A capacitor C2c is coupled to the paths 463 and 483 and stores a charge of Vdrv/4. A capacitor C1c is coupled to the paths 472 and 463 and also stores a charge of Vdrv/4. T1c is coupled at its drain to the path 472 and at its source to the path 463. T2c is coupled at its source to the path 463 and at its drain to the path 483. C2c can transfer charge to, and receive charge from, Cg-PS. For example, the arrow 479 represents charge being transferred from C2c to Cg-PS via the switch 4CS3 at t1 in FIG. 4C2, and the arrow 480 represents charge being transferred in the opposite direction, from Cg-PS to C2c at t7 in FIG. 4C2.

In the second push-pull regulation circuit 457, the third and fourth comparators regulate the voltage at the path 472 (a second regulated path) to Vdrv/2+/−Δ/2 so that there is a hysteresis window of width A centered at Vdrv/2. To achieve this, the third comparator P3c receives Vdrv/2−Δ/2 at a non-inverting input (+) and the regulated voltage at the path 472 at an inverting input (−). Vdrv/2 is a reference voltage. Additionally, the fourth comparator P4c receives Vdrv/2+Δ/2 at a non-inverting input and the regulated voltage at the path 472 at an inverting input. The output path 458 goes high to turn on T3c and thereby increase the voltage at the path 472 when the regulated voltage falls below Vdrv/2−Δ/2. The output path 460 goes low to turn on T4c and thereby decrease the voltage at the path 472 when the regulated voltage increases above Vdrv/2+Δ/2.

A capacitor C3c is coupled to the paths 470 and 472 and stores a charge of Vdrv/4. A capacitor C4c is coupled to the paths 463 and 472 and also stores a charge of Vdrv/4. T3c is coupled at its drain to the path 470 and at its source to the path 472. T4c is coupled at its source to the path 472 and at its drain to the path 463. C4c can transfer charge to, and receive charge from, Cg-PS. For example, the arrow 477 represents charge being transferred from C4c to Cg-PS via the switch 4CS2 at t2 in FIG. 4C2, and the arrow 478 represents charge being transferred in the opposite direction, from Cg-PS to C4c at t6 in FIG. 4C2.

In the third push-pull regulation circuit 465, the fifth and sixth comparators regulate the voltage at the path 470 (a third regulated path) to 3Vdrv/4+/−Δ/2 so that there is a hysteresis window of width A centered at 3Vdrv/4. To achieve this, the fifth comparator P5c receives 3Vdrv/4−Δ/2 at a non-inverting input (+) and the regulated voltage at the path 470 at an inverting input (−). 3Vdrv/4 is a reference voltage. Additionally, the sixth comparator P6c receives 3Vdrv/4+Δ/2 at a non-inverting input and the regulated voltage at the path 470 an inverting input. The output path 466 goes high to turn on T5c and thereby increase the voltage at the path 470 when the regulated voltage falls below 3Vdrv/4−Δ/2. The output path 468 goes low to turn on T6c and thereby decrease the voltage at the path 470 when the regulated voltage increases above 3Vdrv/4+Δ/2.

A capacitor C5c is coupled to the paths 447 and 470 and stores a charge of Vdrv/4. A capacitor C6c is coupled to the paths 470 and 472 and also stores a charge of Vdrv/4. T5c is coupled at its drain to the path 447 and at its source to the path 470. T6c is coupled at its source to the path 470 and at its drain to the path 472. C6c can transfer charge to, and receive charge from, Cg-PS. For example, the arrow 475 represents charge being transferred from C6c to Cg-PS via the switch 4CS1 at t3 in FIG. 4C2, and the arrow 476 represents charge being transferred in the opposite direction, from Cg-PS to C6c via the switch 4CS1 at t5 in FIG. 4C2. The arrow 481 represents charge being transferred from Cg-PS to ground via the switch 4CS4 at t8 in FIG. 4C2.

FIG. 4C2 depicts an example plot of the output voltage Vg versus time for the driver of FIG. 4C1, in accordance with various embodiments. N=4 since there are four voltage steps. For example, starting from 0 V from t0-t1 with 4CS4 closed, there is a first voltage step up to Vdrv/4 at t1-t2 with 4CS3 closed, a second voltage step up from Vdrv/4 to Vdrv/2 at t2-t3 with 4CS2 closed, a third voltage step up from Vdrv/2 to 3Vdrv/4 at t3-t4 with 4CS1 closed, and a fourth voltage step up from 3Vdrv/4 to Vdrv at t4-t5 with 4CS0 closed. Starting from Vdrv, there is a first voltage step down to 3Vdrv/4 at t5-t6 with 4CS1 closed, a second voltage step down from 3Vdrv/4 to Vdrv/2 at t6-t7 with 4CS2 closed, a third voltage step down from Vdrv/2 to Vdrv/4 at t7-t8 with 4CS3 closed, and a fourth voltage step down from Vdrv/4 to 0 V at t8-t9 with 4CS4 closed.

The charge-discharge cycle includes a charge phase from t0-t4 and a discharge phase from t5-t9.

The figure depicts increasing voltage steps 660-663 in a charge phase 668 and decreasing voltage steps 664-667 in a discharge phase 669.

In this example, first, second and third switches and an additional switch of the driver 445 are capable of providing N=4 increasing voltage steps followed by N=4 decreasing voltage steps on the output path in a charge-discharge cycle of the control gate.

Generally, first, second and third switches and an additional switch of a driver may be capable of providing N≥3 increasing voltage steps followed by N≥3 decreasing voltage steps on the output path in a charge-discharge cycle of the control gate.

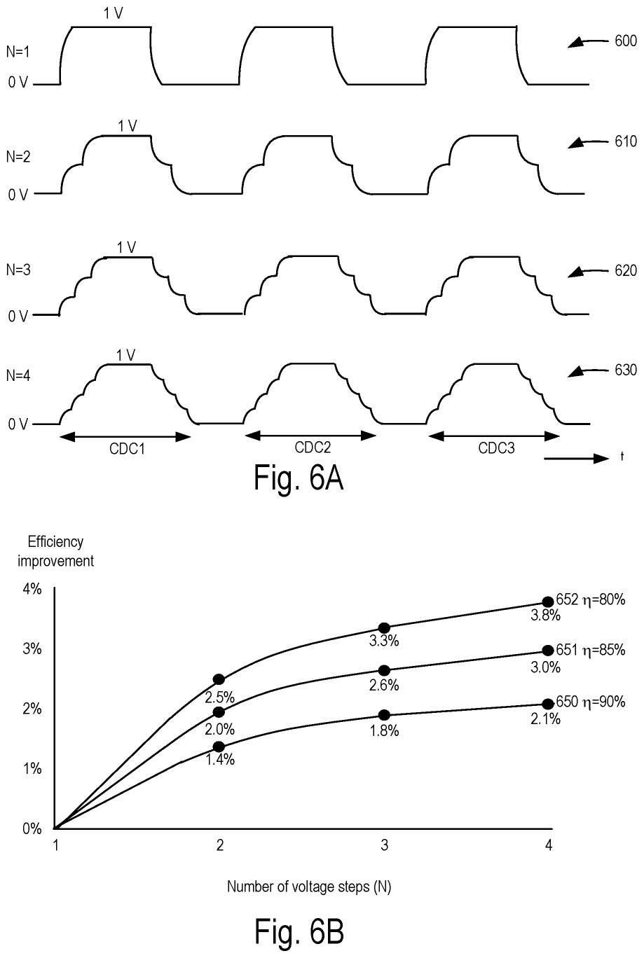

Note that in FIGS. 4A2, 4B2 and 4C2, the duration Thold of the peak voltage Vdrv is depicted as being similar to the duration of each intermediate voltage step for simplicity. In practice, the duration of the peak voltage may be longer than the duration of each intermediate voltage step, as well as longer than Trise and Thold, which may be equal to one another. See also FIGS. 2B and 6A.

FIG. 5A1 depicts an example switched capacitor-based three-level driver, 550 consistent with the charge-recycling circuit 220 of FIG. 2A, in accordance with various embodiments. The driver includes a single flying capacitor Cf (a first flying capacitor) having a voltage of Vf=Vdrv/2. This voltage can be initialized in a setup process by closing 5AS0 and 5AS1 while 5AS2 is open and while Vdrv/2 is applied to the power supply node 551.

The driver provides Vg as an output voltage at a control gate 462 of the power switch, where the control gate has the capacitance Cg-PS as mentioned. Referring also to FIG. 5A2, at t0-t1 when 5AS2 is closed and 5AS1 and 5AS0 are open, the control gate is grounded so that Vg=0 V. Charge flows from Cg-PS to ground as indicated by the arrow 555, so that Cg-PS discharges. At t1-t2, when 5AS1 is closed and 5AS0 and 5AS2 are open, charge flows from Cf to Cg-PS as indicated by the arrow 554 so that Vg=Vdrv/2. At t2-t3, when 5AS0 is closed and 5AS1 and 5AS2 are open, the power supply node is coupled to the control gate so that Vg=Vdrv. Charge flows as indicated by the arrow 552 via the node 560 or output path to charge up Cg-PS to Vdrv. At t3-t4, when 5AS1 is closed and 5AS0 and 5AS2 are open, charge flows from Cg-PS to Cf as indicated by the arrow 553 so that Vg decreases to Vdrv/2. At t4-t5, when 5AS2 is closed and 5AS0 and 5AS1 are open, the control gate is again grounded so that Vg=0 V.

A process for operating the switched capacitor-based three-level driver can involve repeated cycles where each cycle includes, in order, grounding the control gate, coupling a flying capacitor to the control gate to provide an intermediate voltage (Vdrv/2) to the control gate, coupling a peak drive voltage Vdrv to the control gate, coupling the flying capacitor to the control gate to allow the voltage of the control gate to discharge to the intermediate voltage (Vdrv/2), and grounding the control gate.

A control circuit such as the processor circuitry 1052 can provide control signals to switches to perform each cycle. For example, a first switch 5AS0 may be used to couple the power supply node to the control gate, a second switch 5AS1 may be used to couple the flying capacitor to the control gate, and a third switch 5AS2 may be used to couple the control gate to ground. The switches may be transistors for example, which can be turned on or off by applying appropriate voltages to their control gates.

The number of flying capacitors in the driver may be equal to the number of intermediate steps, which is N−1.

The steady-state final voltage across the capacitor Cf can be computed from state equations: Vdrv−Vf=ΔV during charging of Cf and Vf=AV during discharging of Cf.

FIG. 5A2 depicts an example plot of the output voltage Vg versus time for the driver of FIG. 5A1, in accordance with various embodiments. N=2 since there are two voltage steps. For example, starting from 0 V from t0-t1 with 5AS2 closed, there is a first voltage step up to Vdrv/2 (a first intermediate voltage) at t1-t2 with 5AS1 closed, and a second voltage step up from Vdrv/2 to Vdrv at t2-t3 with 5AS0 closed. Starting from Vdrv, there is a first voltage step down to Vdrv/2 at t3-t4 with 5AS1 closed, and a second voltage step down from Vdrv/to 0 V at t4-t5 with 5AS2 closed. The step size is Δ=Vdrv/2.

The charge-discharge cycle includes a charge phase from t0-t2 and a discharge phase from t3-t5.

In an example implementation, an apparatus comprises: a switch 5AS0 coupled to a power supply node 551 and to a node or output path 560; a first flying capacitor Cf; a switch 5AS1 coupled to the first flying capacitor and the output path; and a switch 5AS2 coupled to the output path and ground, wherein: the output path is coupled to a control gate 462 of a power switch 115; and the first, second and third switches are capable of providing N≥2 increasing voltage steps followed by N decreasing voltage steps on the output path in a charge-discharge cycle of the control gate.

Additionally, the switch 5AS1 coupled to the first flying capacitor and the output path is closed to transfer charge from the first flying capacitor Cf to the control gate 462 during a respective step 670 of the N≥2 increasing voltage steps, and to transfer charge to the first flying capacitor from the control gate during a respective step 672 of the N≥2 decreasing voltage steps.

The figure depicts increasing voltage steps 670 and 671 in a charge phase 674 and decreasing voltage steps 672 and 673 in a discharge phase 675.

FIG. 5B1 depicts an example switched capacitor-based four-level driver 570, consistent with the charge-recycling circuit 220 of FIG. 2A, in accordance with various embodiments. The driver includes a first flying capacitor Cf1 having a voltage of Vf1=Vdrv/3 and a second flying capacitor Cf2 having a voltage of Vf2=2Vdrv/3. Vf1 can be initialized in a setup process by closing 5BS0 and 5BS2 while 5BS1 and 5BS3 are open and while Vdrv/3 is applied to the power supply node 551. Vf2 can be initialized in a setup process by closing 5BS0 and 5BS1 while 5BS2 and 5BS3 are open and while 2Vdrv/3 is applied to the power supply node 551.

The driver provides Vg as an output voltage at the control gate 462 of the power switch which has the capacitance Cg-PS. Referring also to FIG. 5B2, at t0-t1 when 5BS3 is closed and 5BS0-5BS2 are open, the control gate is grounded so that Vg=0 V. Charge flows from Cg-PS to ground as indicated by the arrow 576, so that Cg-PS discharges. At t1-t2, when 5BS2 is closed and 5BS0, 5BS1 and 5BS3 are open, charge flows from Cf1 to Cg-PS as indicated by the arrow 575 so that Vg=Vdrv/3. At t2-t3, when 5BS1 is closed and 5BS0, 5BS2 and 5BS3 are open, charge flows from Cf2 to Cg-PS as indicated by the arrow 572 so that Vg=2Vdrv/3. At t3-t4, when 5BS0 is closed and 5BS1-5BS3 are open, the power supply node is coupled to the control gate so that Vg=Vdrv. Charge flows as indicated by the arrow 574 to charge up Cg-PS to Vdrv. At t4-t5, when 5BS1 is closed and 5BS0, 5BS2 and 5BS3 are open, charge flows from Cg-PS to Cf2 as indicated by the arrow 571 so that Vg decreases to 2Vdrv/3. At t5-t6 when 5BS2 is closed and 5BS0, 5BS1 and 5BS3 are open, charge flows from Cg-PS to Cf1 as indicated by the arrow 573 so that Vg decreases to Vdrv/3. At t6-t7 when 5BS3 is closed and 5BS0-5BS2 are open, the control gate is again grounded so that Vg=0 V.

A process for operating the switched capacitor-based four-level driver can involve repeated cycles where each cycle includes, in order, grounding the control gate, coupling a first flying capacitor to the control gate to provide a first intermediate voltage (Vdrv/3) to the control gate, coupling a second flying capacitor to the control gate to provide a second intermediate voltage (2Vdrv/3) to the control gate, coupling a peak drive voltage Vdrv to the control gate, coupling the second flying capacitor to the control gate to allow the voltage of the control gate to discharge to the second intermediate voltage (2Vdrv/3), coupling the first flying capacitor to the control gate to allow the voltage of the control gate to discharge to the first intermediate voltage (Vdrv/3), and grounding the control gate.

A control circuit such as the processor circuitry 1052 can provide control signals to switches to perform each cycle. For example, a first switch 5BS0 may be used to couple the power supply node to the control gate, a second switch 5BS2 may be used to couple the first flying capacitor to the control gate, a third switch 5BS1 may be used to couple the second flying capacitor to the control gate, and a fourth switch 5BS3 may be used to couple the control gate to ground.

The steady-state final voltage across the capacitors can be computed from state equations: 1) Vdrv−Vf2=AV during charging of Cf2; 2) Vf2−Vf1=ΔV during charging of Cf1 and discharging of Cf2; and 3) Vf1=ΔV during discharging of Cf1.

FIG. 5B2 depicts an example plot of the output voltage Vg versus time for the driver of FIG. 5B1, in accordance with various embodiments. N=3 since there are three voltage steps. For example, starting from 0 V from t0-t1 with 5BS3 closed, there is a first voltage step up to Vdrv/3 at t1-t2 with 5BS2 closed, a second voltage step up from Vdrv/3 to 2Vdrv/3 at t2-t3 with 5BS1 closed, and a third voltage step up from 2Vdrv/3 to Vdrv at t3-t4 with 5BS0 closed. Starting from Vdrv, there is a first voltage step down to 2Vdrv/3 at t4-t5 with 5BS1 closed, a second voltage step down from 2Vdrv/3 to Vdrv/3 at t5-t6 with 5BS2 closed, and a third step down to 0 V at t6-t7 with 5BS3 closed. The step size is Δ=Vdrv/3.

The charge-discharge cycle includes a charge phase from t0-t3 and a discharge phase from t4-t7.

The figure depicts increasing voltage steps 680-682 in a charge phase 686 and decreasing voltage steps 683-685 in a discharge phase 687.

FIG. 5C1 depicts an example switched capacitor-based five-level driver 590, consistent with the charge-recycling circuit 220 of FIG. 2A, in accordance with various embodiments. The driver includes a first flying capacitor Cf1 having a voltage of Vf1=Vdrv/4, a second flying capacitor Cf2 having a voltage of Vf2=Vdrv/2 and a third flying capacitor Cf3 having a voltage of Vf3=3Vdrv/4. Vf1 can be initialized in a setup process by closing 5CS0 and 5CS3 while 5CS1, 5CS2 and 5CS4 are open and while Vdrv/4 is applied to the power supply node 551. Vf2 can be initialized in a setup process by closing 5CS0 and 5CS2 while 5CS1, 5CS3 and 5CS4 are open and while Vdrv/2 is applied to the power supply node 551. Vf3 can be initialized in a setup process by closing 5CS0 and 5CS1 while 5CS2-5CS4 are open and while 3Vdrv/4 is applied to the power supply node 551.

The driver provides Vg as an output voltage at the control gate 462 of the power switch which has the capacitance Cg-PS. Referring also to FIG. 5C2, at t0-t1 when 5CS4 is closed, the control gate is grounded so that Vg-0 V. Charge flows from Cg-PS to ground as indicated by the arrow 598, so that Cg-PS discharges. At t1-t2, when 5CS3 is closed, charge flows from Cf1 to Cg-PS as indicated by the arrow 597 so that Vg=Vdrv/4. At t2-t3, when 5CS2 is closed, charge flows from Cf2 to Cg-PS as indicated by the arrow 596 so that Vg=Vdrv/2. At t3-t4, when 5CS1 is closed, charge flows from Cf3 to Cg-PS as indicated by the arrow 592 so that Vg=3Vdrv/4. At t4-t5, when 5CS0 is closed, the power supply node is coupled to the control gate so that Vg=Vdrv. Charge flows as indicated by the arrow 594 to charge up Cg-PS to Vdrv. At t5-t6, when 5CS1 is closed, charge flows from Cg-PS to Cf3 as indicated by the arrow 591 so that Vg decreases to 3Vdrv/4. At t6-t7 when 5CS2 is closed, charge flows from Cg-PS to Cf2 as indicated by the arrow 593 so that Vg decreases to Vdrv/2. At t7-t8 when 5CS3 is closed, charge flows from Cg-PS to Cf1 as indicated by the arrow 595 so that Vg decreases to Vdrv/4. At t8-t9 when 5CS4 is closed, the control gate is again grounded so that Vg=0 V.

A process for operating the switched capacitor-based five-level driver can involve repeated cycles where each cycle includes, in order, grounding the control gate, coupling a first flying capacitor to the control gate to provide a first intermediate voltage (Vdrv/4) to the control gate, coupling a second flying capacitor to the control gate to provide a second intermediate voltage (Vdrv/2) to the control gate, coupling a third flying capacitor to the control gate to provide a third intermediate voltage (3Vdrv/4) to the control gate, coupling a peak drive voltage Vdrv to the control gate, coupling the third flying capacitor to the control gate to allow the voltage of the control gate to discharge to the third intermediate voltage (3Vdrv/4), coupling the second flying capacitor to the control gate to allow the voltage of the control gate to discharge to the second intermediate voltage (Vdrv/2), coupling the first flying capacitor to the control gate to allow the voltage of the control gate to discharge to the first intermediate voltage (Vdrv/4), and grounding the control gate.

A control circuit such as the processor circuitry 1052 can provide control signals to switches to perform each cycle. For example, a first switch 5CS0 may be used to couple the power supply node to the control gate, a second switch 5CS3 may be used to couple the first flying capacitor to the control gate, a third switch 5CS2 may be used to couple the second flying capacitor to the control gate, a fourth switch 5CS1 may be used to couple the third flying capacitor to the control gate, and a fifth switch 5CS4 may be used to couple the control gate to ground.

The steady-state final voltage across the capacitors can be computed from state equations: 1) Vdrv−Vf3=AV during charging of Cf3; 2) Vf3−Vf2=ΔV during charging of Cf2 and discharging of Cf3; 3) Vf2−Vf1=ΔV during charging of Cf1 and discharging of Cf2; and 4) Vf1=ΔV during discharging of Cf1.

FIG. 5C2 depicts an example plot of the output voltage Vg versus time for the driver of FIG. 5C1, in accordance with various embodiments. N=4 since there are four voltage steps. For example, starting from 0 V from t0-t1 with 5CS4 closed, there is a first voltage step up to Vdrv/4 at t1-t2 with 5CS3 closed, a second voltage step up from Vdrv/4 to Vdrv/2 at t2-t3 with 5CS2 closed, a third voltage step up from Vdrv/2 to 3Vdrv/4 at t3-t4 with 5CS1 closed, and a fourth voltage step up from 3Vdrv/4 to Vdrv at t4-t5 with 5CS0 closed. Starting from Vdrv, there is a first voltage step down to 3Vdrv/4 at t5-t6 with 5CS1 closed, a second voltage step down from 3Vdrv/4 to Vdrv/2 at t6-t7 with 5CS2 closed, a third voltage step down from Vdrv/2 to Vdrv/4 at t7-t8 with 5CS3 closed, and a fourth step down to 0 V at t8-t9 with 5CS4 closed. The step size is Δ=Vdrv/4. The cycle includes a charge phase from t0-t4 in which Vg is increased step wise followed by a discharge phase from t5-t9 in which Vg is decreased step wise.

The figure depicts increasing voltage steps 690-693 in a charge phase 698 and decreasing voltage steps 694-697 in a discharge phase 699.

FIG. 6A depicts plots of gate voltage versus time for different numbers of voltage steps (N), in accordance with various embodiments. This is the control gate voltage at the power switch. The gate voltage varies from 0 V to 1 V and back to 0 V in successive charge-discharge cycles CDC1, CDC2 and CDC3 in each example. The plots 600, 610, 620 and 630 represents the case of N=1, 2, 3 and 4, respectively. These are simulated gate voltage waveforms. Generally, the charge-discharge cycles can continue as long as the voltage regulator is operating. The duration of a charge-discharge cycle could be adjusted over time in some cases.

FIG. 6B depicts a plot of efficiency improvement (%) versus number of voltage steps (N), in accordance with various embodiments. The efficiency (η) increases as a result of using a multi-level driver as described herein. The plots 650, 651 and 652 depict the efficiency improvement for a DC-DC voltage converter with an assumed initial efficiency of η=90%, 85% and 80%, respectively, with a two-level driver (N=1). With an initial efficiency of η=90%, plot 650 shows that the efficiency improves by 1.4%, 1.8% and 2.1% for N=2, 3 and 4, respectively. As discussed, N=2, 3 and 4 corresponds to a 3, 4 or 5-level driver, respectively. With an initial efficiency of η=85%, plot 651 shows that the efficiency improves by 2.0%, 2.6% and 3.0% for N=2, 3 and 4, respectively. With an initial efficiency of η=80%, plot 652 shows that the efficiency improves by 2.5%, 3.3% and 3.8% for N=2, 3 and 4, respectively. The gate loss power is assumed to be 30% of the total power loss. Generally, the efficiency improvement is greater when the starting efficiency is lower. Also, the efficiency improvement increases as N increases.

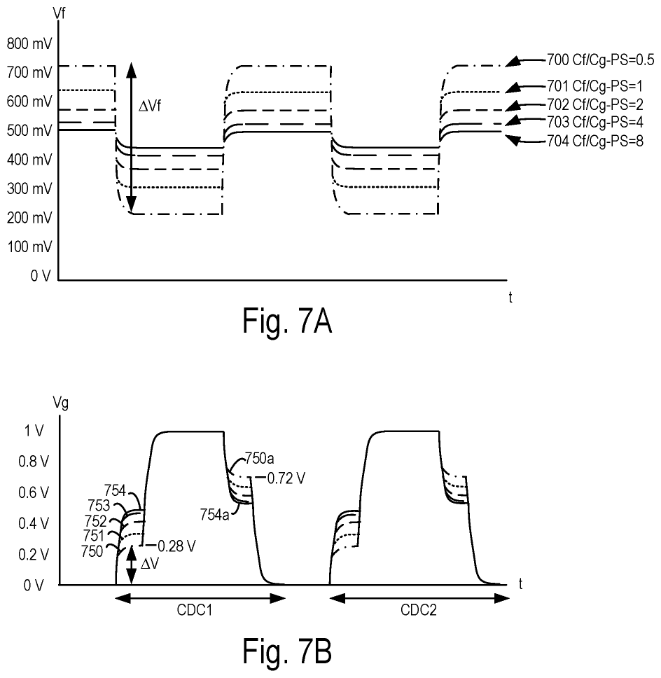

FIG. 7A depicts a plot of a flying capacitor voltage (Vf) versus time for a three-level driver, consistent with FIG. 5A1, in accordance with various embodiments. The data is for the driver 550 of FIG. 5A1 which includes the flying capacitor Cf. The plots correspond to different ratios of Cf/Cg-PS, where Cg-PS is the capacitance of the control gate of the power switch, also referred to as a load capacitance. In particular, the plots 700, 701, 702, 703 and 704 correspond to Cf/Cg-PS=0.5, 1, 2, 4 and 8, respectively. Generally, as the ratio increases, the variation or ripple in Vf (ΔVf) decreases. A smaller capacitance results in an increased voltage ripple across the flying capacitor, resulting in an increase in charge-sharing losses and unsymmetrical gate voltage waveforms which result in more losses.

A maximum ΔVf in this example is about 500 mV. The ripple can therefore be minimized by configuring the capacitances so that the ratio is sufficiently large. The ideal level of Vf in this example is 500 mV. In the examples discussed previously at FIG. 5A1-5C2, the voltage of the flying capacitor was assumed to be at an ideal level such as Vdr/2, or Vdrv/3 and 2Vdrv/3, or Vdrv/4, Vdrv/2 and 3Vdrv/4. FIG. 7A shows that these ideal levels, or close to the ideal levels, can be achieved when the ratio of Cf/Cg-PS is sufficiently large, e.g., when Cf exceeds Cg-PS by a sufficient amount.

FIG. 7B depicts a plot of a control gate voltage (Vg), consistent with FIG. 7A, in accordance with various embodiments. The plots 750-754 correspond to, and are time-aligned with, the plots 700-704, respectively, in FIG. 7A. Vg is depicted over example charge-discharge cycles CDC1 and CDC2 and varies based on the impact of the ripple in FIG. 7A. When Cf is relatively low compared to Cg-PS, it is limited in how much charge it can transfer to, or receive from, Cg-PS. For example, during the charging up of Cg-PS, when Cf is relatively small (Cf/Cg-PS=0.5), Vg increases to a relatively low voltage such as 0.28 V as depicted by the plot 750. This is less than the ideal level of 0.5 V. When Cf is relatively large (Cf/Cg-PS=8), Vg increases to, or close to, within a small tolerance, of the ideal level of 0.5 V as depicted by the plot 754.

Similarly, during the discharging of Cg-PS, when Cf is relatively small, Vg decreases to a relatively high voltage such as 0.72 V as depicted by the plot 750a. This is less than the ideal level of 0.5 V. When Cf is relatively large (Cf/Cg-PS=8), Vg decreases to, or close to, within a small tolerance, of the ideal level of 0.5 V as depicted by the plot 754a.

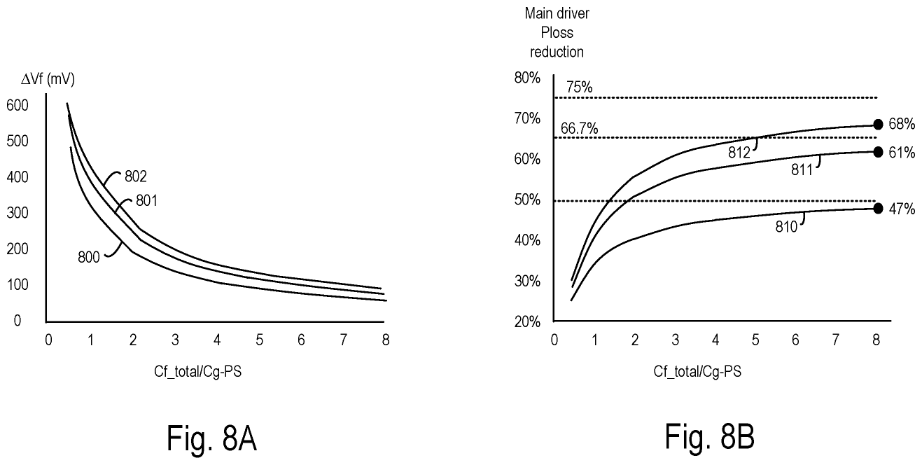

FIG. 8A depicts a plot of a flying capacitor voltage ripple (ΔVf) versus capacitance ratio for different numbers of voltage steps (N), consistent with FIGS. 5A1, 5B1 and 5C1, in accordance with various embodiments. The total capacitance ratio is Cf_total/Cg-PS, which varies between 0.5 and 8.0 in this example. When a driver includes one flying capacitor (N=2), Cf_total represents the capacitance of that one flying capacitor. When a driver includes multiple flying capacitor (N=3 or more), Cf_total represents the total capacitance of the flying capacitors, e.g., the sum of their individual capacitances. Also, for a given ratio, ΔVf increases slightly with N.

The plots 800, 801 and 802 depict the ripple for N=2, 3 and 4, respectively. As the ratio (and the total flying capacitance) increases, the voltage ripple decreases.

FIG. 8B depicts a plot of a main driver Ploss reduction versus capacitance ratio for different numbers of voltage steps (N), consistent with FIG. 8A, in accordance with various embodiments. The plots 810, 811 and 812 depict the Ploss reduction for N=2, 3 and 4, respectively. As the ratio increases, charge sharing losses decrease and the Ploss reduction increases, approaching the ideal percentage of Ploss reduction. Also, for a given ratio, Ploss reduction increases with N.

For N=2 (plot 810), the Ploss reduction reaches 47% with Cf_total/Cg-PS=8, while the ideal Ploss reduction is 50% (since 100%×(1−1/N)=50%). For N=3 (plot 811), the Ploss reduction reaches 61% with Cf_total/Cg-PS=8, while the ideal Ploss reduction is 66.7% (since 100%×(1−⅓)=66.7%). For N=4 (plot 812), the Ploss reduction reaches 68% with Cf_total/Cg-PS=8, while the ideal Ploss reduction is 75% (since 100%×(1−¼)=75%). Accordingly, as the total flying capacitance increases, the power loss reduction increases, approaching the ideal percentage of loss reduction. The Ploss reduction can be increased by increasing the capacitance of the flying capacitors. However, there is a space penalty as the flying capacitors become larger. Accordingly, a tradeoff can be made between Ploss reduction and space based on design considerations.

FIG. 9 depicts an example DC-to-DC voltage converter 900 which includes a high-side driver (HSD) and a low-side driver (LSD), in accordance with various embodiments. The converter provides an example circuit in which the drivers as discussed above, e.g., in connection with FIG. 4A1-5C2, can be used. This example includes two drivers which can each use the efficient driver solution as discussed herein. A high-side driver (HSD) provides a control gate voltage VgHS for a respective transistor THS, and a low-side driver (LSD) provides a control gate voltage VgLS for a transistor TLS. The converter design is a buck converter in which the transistors are alternately turned on and off according to respective duty cycles to maintain an output voltage Vout at a desired level.

The transistors THS and LHS are arranged serially, and can be considered to be drive or power transistors or switches in a power stage (PS) of the voltage converter. THS is coupled at its drain to a power supply 950 at Vin and TLS is coupled at its source to ground G. An output node 905 between, and coupled to, the two transistors in a serial path from the power supply 950 to ground, has a voltage Vout which is provided to an inductor L to generate a current Iload. THS has a control gate 951 which is driven by a voltage VgHS on a path 906 from the HSD. Similarly, TLS has a control gate 952 which is driven by a voltage VgLS on a path 907 from the LSD.

The HSD is controlled by signals on a first input path HSD1 and a second input path HSD2. HSD1 and HSD2 are provided by a switch SW coupled to a power supply node 930 at a drive voltage, Vdrv. The switch may be controlled by a signal dLS bar, which is opposite in polarity to dLS. The signal on HSD2 is provided via a path 931 which is coupled to the switch via a capacitor C. HSD2 is a delayed version of HSD1 due to the capacitor C. A diode D is also depicted

The LSD is controlled by a drive signal dLS on an input path 940 and by Vout on a feedback path 941. The LSD also receives Vdrv via a path 932.

FIG. 10 illustrates an example of components that may be present in a computing system 1050 for implementing the techniques (e.g., operations, processes, methods, and methodologies) described herein. The voltage converter 1000 may provide a voltage Vout to one or more of the components of the computing system 1050. The voltage converter may be controlled by control signals provided by the processor circuitry 1052. The voltage converter may include drivers such as discussed in connection with FIG. 4A1-5C2.

The memory circuitry 1054 may store instructions and the processor circuitry 1052 may execute the instructions to perform the functions described herein.

The computing system 1050 may include any combinations of the hardware or logical components referenced herein. The components may be implemented as ICs, portions thereof, discrete electronic devices, or other modules, instruction sets, programmable logic or algorithms, hardware, hardware accelerators, software, firmware, or a combination thereof adapted in the computing system 1050, or as components otherwise incorporated within a chassis of a larger system. For one embodiment, at least one processor 1052 may be packaged together with computational logic 1082 and configured to practice aspects of various example embodiments described herein to form a System in Package (SiP) or a System on Chip (SoC).

The system 1050 includes processor circuitry in the form of one or more processors 1052. The processor circuitry 1052 includes circuitry such as, but not limited to one or more processor cores and one or more of cache memory, low drop-out voltage regulators (LDOs), interrupt controllers, serial interfaces such as SPI, I2C or universal programmable serial interface circuit, real time clock (RTC), timer-counters including interval and watchdog timers, general purpose I/O, memory card controllers such as secure digital/multi-media card (SD/MMC) or similar, interfaces, mobile industry processor interface (MIPI) interfaces and Joint Test Access Group (JTAG) test access ports. In some implementations, the processor circuitry 1052 may include one or more hardware accelerators (e.g., same or similar to acceleration circuitry 1064), which may be microprocessors, programmable processing devices (e.g., FPGA, ASIC, etc.), or the like. The one or more accelerators may include, for example, computer vision and/or deep learning accelerators. In some implementations, the processor circuitry 1052 may include on-chip memory circuitry, which may include any suitable volatile and/or non-volatile memory, such as DRAM, SRAM, EPROM, EEPROM, Flash memory, solid-state memory, and/or any other type of memory device technology, such as those discussed herein

The processor circuitry 1052 may include, for example, one or more processor cores (CPUs), application processors, GPUs, RISC processors, Acorn RISC Machine (ARM) processors, CISC processors, one or more DSPs, one or more FPGAs, one or more PLDs, one or more ASICs, one or more baseband processors, one or more radio-frequency integrated circuits (RFIC), one or more microprocessors or controllers, a multi-core processor, a multithreaded processor, an ultra-low-voltage processor, an embedded processor, or any other known processing elements, or any suitable combination thereof. The processors (or cores) 1052 may be coupled with or may include memory/storage and may be configured to execute instructions stored in the memory/storage to enable various applications or operating systems to run on the platform 1050. The processors (or cores) 1052 is configured to operate application software to provide a specific service to a user of the platform 1050. In some embodiments, the processor(s) 1052 may be a special-purpose processor(s)/controller(s) configured (or configurable) to operate according to the various embodiments herein.

As examples, the processor(s) 1052 may include an Intel® Architecture Core™ based processor such as an i3, an i5, an i7, an i9 based processor; an Intel® microcontroller-based processor such as a Quark™, an Atom™, or other MCU-based processor; Pentium® processor(s), Xeon® processor(s), or another such processor available from Intel® Corporation, Santa Clara, California. However, any number other processors may be used, such as one or more of Advanced Micro Devices (AMD) Zen® Architecture such as Ryzen® or EPYC® processor(s), Accelerated Processing Units (APUs), MxGPUs, Epyc® processor(s), or the like; A5-A12 and/or S1-S4 processor(s) from Apple® Inc., Snapdragon™ or Centriq™ processor(s) from Qualcomm® Technologies, Inc., Texas Instruments, Inc.® Open Multimedia Applications Platform (OMAP)™ processor(s); a MIPS-based design from MIPS Technologies, Inc. such as MIPS Warrior M-class, Warrior I-class, and Warrior P-class processors; an ARM-based design licensed from ARM Holdings, Ltd., such as the ARM Cortex-A, Cortex-R, and Cortex-M family of processors; the ThunderX2® provided by Cavium™, Inc.; or the like. In some implementations, the processor(s) 1052 may be a part of a system on a chip (SoC), System-in-Package (SiP), a multi-chip package (MCP), and/or the like, in which the processor(s) 1052 and other components are formed into a single integrated circuit, or a single package, such as the Edison™ or Galileo™ SoC boards from Intel® Corporation. Other examples of the processor(s) 1052 are mentioned elsewhere in the present disclosure.

The system 1050 may include or be coupled to acceleration circuitry 1064, which may be embodied by one or more AI/ML accelerators, a neural compute stick, neuromorphic hardware, an FPGA, an arrangement of GPUs, one or more SoCs (including programmable SoCs), one or more CPUs, one or more digital signal processors, dedicated ASICs (including programmable ASICs), PLDs such as complex (CPLDs) or high complexity PLDs (HCPLDs), and/or other forms of specialized processors or circuitry designed to accomplish one or more specialized tasks. These tasks may include AI/ML processing (e.g., including training, inferencing, and classification operations), visual data processing, network data processing, object detection, rule analysis, or the like. In FPGA-based implementations, the acceleration circuitry 1064 may comprise logic blocks or logic fabric and other interconnected resources that may be programmed (configured) to perform various functions, such as the procedures, methods, functions, etc. of the various embodiments discussed herein. In such implementations, the acceleration circuitry 1064 may also include memory cells (e.g., EPROM, EEPROM, flash memory, static memory (e.g., SRAM, anti-fuses, etc.) used to store logic blocks, logic fabric, data, etc. in LUTs and the like.

In some implementations, the processor circuitry 1052 and/or acceleration circuitry 1064 may include hardware elements specifically tailored for machine learning and/or artificial intelligence (AI) functionality. In these implementations, the processor circuitry 1052 and/or acceleration circuitry 1064 may be, or may include, an AI engine chip that can run many different kinds of AI instruction sets once loaded with the appropriate weightings and training code. Additionally or alternatively, the processor circuitry 1052 and/or acceleration circuitry 1064 may be, or may include, AI accelerator(s), which may be one or more of the aforementioned hardware accelerators designed for hardware acceleration of AI applications. As examples, these processor(s) or accelerators may be a cluster of artificial intelligence (AI) GPUs, tensor processing units (TPUs) developed by Google® Inc., Real AI Processors (RAPS™) provided by AlphaICs®, Nervana™ Neural Network Processors (NNPs) provided by Intel® Corp., Intel® Movidius™ Myriad™ X Vision Processing Unit (VPU), NVIDIA® PX™ based GPUs, the NM500 chip provided by General Vision®, Hardware 3 provided by Tesla®, Inc., an Epiphany™ based processor provided by Adapteva®, or the like. In some embodiments, the processor circuitry 1052 and/or acceleration circuitry 1064 and/or hardware accelerator circuitry may be implemented as AI accelerating co-processor(s), such as the Hexagon 685 DSP provided by Qualcomm®, the PowerVR 2NX Neural Net Accelerator (NNA) provided by Imagination Technologies Limited®, the Neural Engine core within the Apple® A11 or A12 Bionic SoC, the Neural Processing Unit (NPU) within the HiSilicon Kirin 970 provided by Huawei®, and/or the like. In some hardware-based implementations, individual subsystems of system 1050 may be operated by the respective AI accelerating co-processor(s), AI GPUs, TPUs, or hardware accelerators (e.g., FPGAs, ASICs, DSPs, SoCs, etc.), etc., that are configured with appropriate logic blocks, bit stream(s), etc. to perform their respective functions.

The system 1050 also includes system memory 1054. Any number of memory devices may be used to provide for a given amount of system memory. As examples, the memory 1054 may be, or include, volatile memory such as random access memory (RAM), static RAM (SRAM), dynamic RAM (DRAM), synchronous DRAM (SDRAM), RAMBUS® Dynamic Random Access Memory (RDRAM®), and/or any other desired type of volatile memory device. Additionally or alternatively, the memory 1054 may be, or include, non-volatile memory such as read-only memory (ROM), erasable programmable ROM (EPROM), electrically erasable programmable (EEPROM), flash memory, non-volatile RAM, ferroelectric RAM, phase-change memory (PCM), flash memory, and/or any other desired type of non-volatile memory device. Access to the memory 1054 is controlled by a memory controller. The individual memory devices may be of any number of different package types such as single die package (SDP), dual die package (DDP) or quad die package (Q17P). Any number of other memory implementations may be used, such as dual inline memory modules (DIMMs) of different varieties including but not limited to microDIMMs or MiniDIMMs.

Storage circuitry 1058 provides persistent storage of information such as data, applications, operating systems and so forth. In an example, the storage 1058 may be implemented via a solid-state disk drive (SSDD) and/or high-speed electrically erasable memory (commonly referred to as “flash memory”). Other devices that may be used for the storage 1058 include flash memory cards, such as SD cards, microSD cards, XD picture cards, and the like, and USB flash drives. In an example, the memory device may be or may include memory devices that use chalcogenide glass, multi-threshold level NAND flash memory, NOR flash memory, single or multi-level Phase Change Memory (PCM), a resistive memory, nanowire memory, ferroelectric transistor random access memory (FeTRAM), anti-ferroelectric memory, magnetoresistive random access memory (MRAM) memory that incorporates memristor technology, phase change RAM (PRAM), resistive memory including the metal oxide base, the oxygen vacancy base and the conductive bridge Random Access Memory (CB-RAM), or spin transfer torque (STT)-MRAM, a spintronic magnetic junction memory based device, a magnetic tunneling junction (MTJ) based device, a Domain Wall (DW) and Spin Orbit Transfer (SOT) based device, a thyristor based memory device, a hard disk drive (HDD), micro HDD, of a combination thereof, and/or any other memory. The memory circuitry 1054 and/or storage circuitry 1058 may also incorporate three-dimensional (3D) cross-point (XPOINT) memories from Intel® and Micron®.

The memory circuitry 1054 and/or storage circuitry 1058 is/are configured to store computational logic 1083 in the form of software, firmware, microcode, or hardware-level instructions to implement the techniques described herein. The computational logic 1083 may be employed to store working copies and/or permanent copies of programming instructions, or data to create the programming instructions, for the operation of various components of system 1050 (e.g., drivers, libraries, application programming interfaces (APIs), etc.), an operating system of system 1050, one or more applications, and/or for carrying out the embodiments discussed herein. The computational logic 1083 may be stored or loaded into memory circuitry 1054 as instructions 1082, or data to create the instructions 1082, which are then accessed for execution by the processor circuitry 1052 to carry out the functions described herein. The processor circuitry 1052 and/or the acceleration circuitry 1064 accesses the memory circuitry 1054 and/or the storage circuitry 1058 over the interconnect (IX) 1056. The instructions 1082 direct the processor circuitry 1052 to perform a specific sequence or flow of actions, for example, as described with respect to flowchart(s) and block diagram(s) of operations and functionality depicted previously. The various elements may be implemented by assembler instructions supported by processor circuitry 1052 or high-level languages that may be compiled into instructions 1088, or data to create the instructions 1088, to be executed by the processor circuitry 1052. The permanent copy of the programming instructions may be placed into persistent storage devices of storage circuitry 1058 in the factory or in the field through, for example, a distribution medium (not shown), through a communication interface (e.g., from a distribution server (not shown)), over-the-air (OTA), or any combination thereof.

The IX 1056 couples the processor 1052 to communication circuitry 1066 for communications with other devices, such as a remote server (not shown) and the like. The communication circuitry 1066 is a hardware element, or collection of hardware elements, used to communicate over one or more networks 1063 and/or with other devices. In one example, communication circuitry 1066 is, or includes, transceiver circuitry configured to enable wireless communications using any number of frequencies and protocols such as, for example, the Institute of Electrical and Electronics Engineers (IEEE) 802.11 (and/or variants thereof), IEEE 802.23.4, Bluetooth® and/or Bluetooth® low energy (BLE), ZigBee®, LoRaWAN™ (Long Range Wide Area Network), a cellular protocol such as 3GPP LTE and/or Fifth Generation (5G)/New Radio (NR), and/or the like. Additionally or alternatively, communication circuitry 1066 is, or includes, one or more network interface controllers (NICs) to enable wired communication using, for example, an Ethernet connection, Controller Area Network (CAN), Local Interconnect Network (LIN), DeviceNet, ControlNet, Data Highway+, or PROFINET, among many others.

The IX 1056 also couples the processor 1052 to interface circuitry 1070 that is used to connect system 1050 with one or more external devices 1072. The external devices 1072 may include, for example, sensors, actuators, positioning circuitry (e.g., global navigation satellite system (GNSS)/Global Positioning System (GPS) circuitry), client devices, servers, network appliances (e.g., switches, hubs, routers, etc.), integrated photonics devices (e.g., optical neural network (ONN) integrated circuit (IC) and/or the like), and/or other like devices.

In some optional examples, various input/output (I/O) devices may be present within or connected to, the system 1050, which are referred to as input circuitry 1086 and output circuitry 1084. The input circuitry 1086 and output circuitry 1084 include one or more user interfaces designed to enable user interaction with the platform 1050 and/or peripheral component interfaces designed to enable peripheral component interaction with the platform 1050. Input circuitry 1086 may include any physical or virtual means for accepting an input including, inter alia, one or more physical or virtual buttons (e.g., a reset button), a physical keyboard, keypad, mouse, touchpad, touchscreen, microphones, scanner, headset, and/or the like. The output circuitry 1084 may be included to show information or otherwise convey information, such as sensor readings, actuator position(s), or other like information. Data and/or graphics may be displayed on one or more user interface components of the output circuitry 1084. Output circuitry 1084 may include any number and/or combinations of audio or visual display, including, inter alia, one or more simple visual outputs/indicators (e.g., binary status indicators (e.g., light emitting diodes (LEDs)) and multi-character visual outputs, or more complex outputs such as display devices or touchscreens (e.g., Liquid Crystal Displays (LCD), LED displays, quantum dot displays, projectors, etc.), with the output of characters, graphics, multimedia objects, and the like being generated or produced from the operation of the platform 1050. The output circuitry 1084 may also include speakers and/or other audio emitting devices, printer(s), and/or the like. Additionally or alternatively, sensor(s) may be used as the input circuitry 1084 (e.g., an image capture device, motion capture device, or the like) and one or more actuators may be used as the output device circuitry 1084 (e.g., an actuator to provide haptic feedback or the like). Peripheral component interfaces may include, but are not limited to, a non-volatile memory port, a USB port, an audio jack, a power supply interface, etc. In some embodiments, a display or console hardware, in the context of the present system, may be used to provide output and receive input of an edge computing system; to manage components or services of an edge computing system; identify a state of an edge computing component or service; or to conduct any other number of management or administration functions or service use cases.

The components of the system 1050 may communicate over the IX 1056. The IX 1056 may include any number of technologies, including ISA, extended ISA, I2C, SPI, point-to-point interfaces, power management bus (PMBus), PCI, PCIe, PCIx, Intel® UPI, Intel® Accelerator Link, Intel® CXL, CAPI, OpenCAPI, Intel® QPI, UPI, Intel® OPA IX, RapidIO™ system IXs, CCIX, Gen-Z Consortium IXs, a HyperTransport interconnect, NVLink provided by NVIDIA®, a Time-Trigger Protocol (TTP) system, a FlexRay system, PROFIBUS, and/or any number of other IX technologies. The IX 1056 may be a proprietary bus, for example, used in a SoC based system.

The number, capability, and/or capacity of the elements of system 1050 may vary, depending on whether computing system 1050 is used as a stationary computing device (e.g., a server computer in a data center, a workstation, a desktop computer, etc.) or a mobile computing device (e.g., a smartphone, tablet computing device, laptop computer, game console, IoT device, etc.). In various implementations, the computing device system 1050 may comprise one or more components of a data center, a desktop computer, a workstation, a laptop, a smartphone, a tablet, a digital camera, a smart appliance, a smart home hub, a network appliance, and/or any other device/system that processes data.

The techniques described herein can be performed partially or wholly by software or other instructions provided in a machine-readable storage medium (e.g., memory). The software is stored as processor-executable instructions (e.g., instructions to implement any other processes discussed herein). Instructions associated with the flowchart (and/or various embodiments) and executed to implement embodiments of the disclosed subject matter may be implemented as part of an operating system or a specific application, component, program, object, module, routine, or other sequence of instructions or organization of sequences of instructions.

The storage medium can be a tangible, non-transitory machine readable medium such as read only memory (ROM), random access memory (RAM), flash memory devices, floppy and other removable disks, magnetic storage media, optical storage media (e.g., Compact Disk Read-Only Memory (CD ROMS), Digital Versatile Disks (DVDs)), among others.

The storage medium may be included, e.g., in a communication device, a computing device, a network device, a personal digital assistant, a manufacturing tool, a mobile communication device, a cellular phone, a notebook computer, a tablet, a game console, a set top box, an embedded system, a TV (television), or a personal desktop computer.

Some non-limiting examples of various embodiments are presented below.

Example 1 includes an apparatus, comprising: a supply path coupled to a voltage source; a first switch coupled to an output path and the supply path; first and second transistors coupled to one another serially, wherein the first and second transistors are capable of regulating a voltage of a first regulated path coupled between the first and second transistors to a first intermediate voltage; a second switch coupled to the output path and to the first regulated path; and a third switch coupled to ground and to the output path; wherein: the first switch is capable of coupling a peak drive voltage of the voltage source to the output path; the second switch is capable of coupling the first intermediate voltage to the output path; and the third switch is capable of grounding the output path.

Example 2 includes the apparatus of Example 1, wherein: the output path is coupled to a control gate of a power switch; and the first, second and third switches are capable of providing N≥2 increasing voltage steps followed by N decreasing voltage steps on the output path in a charge-discharge cycle of the control gate.

Example 3 includes the apparatus of Example 2, wherein the N≥2 increasing voltage steps comprise the first intermediate voltage followed by the peak drive voltage and the N≥2 decreasing voltage steps comprise the first intermediate voltage followed by a ground voltage.

Example 4 includes the apparatus of any one of Examples 1-3, further comprising: a first comparator coupled to a control gate of the first transistor; and a second comparator coupled to a control gate of the second transistor; wherein: the first comparator has a non-inverting input coupled to a reference voltage minus a hysteresis increment and an inverting input coupled to the first regulated path; and the second comparator has a non-inverting input coupled to the reference voltage plus the hysteresis increment, and an inverting input coupled to the first regulated path.

Example 5 includes the apparatus of any one of Examples 1-4, wherein the first and second transistors are in a push-pull configuration.

Example 6 includes the apparatus of any one of Examples 1-5, wherein the first transistor comprises an n-type metal-oxide-semiconductor field-effect transistor (MOSFET) and the second transistor comprises a p-type MOSFET.

Example 7 includes the apparatus of any one of Examples 1-6, further comprising: third and fourth transistors coupled to one another serially, wherein the third and fourth transistors are capable of regulating a voltage of a second regulated path coupled between the third and fourth transistors to a second intermediate voltage; and an additional switch coupled to the output path and to the second regulated path, wherein the additional switch is capable of coupling the second intermediate voltage to the output path.

Example 8 includes the apparatus of Example 7, wherein: the output path is coupled to a control gate of a power switch; and the first, second and third switches and the additional switch are capable of providing N≥3 increasing voltage steps followed by N≥3 decreasing voltage steps on the output path in a charge-discharge cycle of the control gate.

Example 9 includes the apparatus of Example 8, wherein: the N≥3 increasing voltage steps comprise the first intermediate voltage followed by the second intermediate voltage followed by the peak drive voltage; and the N≥3 decreasing voltage steps comprise the second intermediate voltage followed by the first intermediate voltage followed by a ground voltage.

Example 10 includes the apparatus of any one of Examples 1-9, further comprising: a first capacitor coupled in parallel with the first transistor, between the path coupled to the voltage source and the first regulated path; and a second capacitor coupled in parallel with the second transistor, between the first regulated path and a ground node.

Example 11 includes the apparatus of any one of Examples 1-10, further comprising at least one of a voltage converter, an integrated circuit, a System on Chip, a System in Package or a computing device in which the supply path, the first switch, the first and second transistors, the second switch, and the third switch are provided.

Example 12 includes an apparatus, comprising: a switch coupled to a power supply node and to an output path; a first flying capacitor; a switch coupled to the first flying capacitor and the output path; and a switch coupled to the output path and ground, wherein: the output path is coupled to a control gate of a power switch; and the switches are capable of providing N≥2 increasing voltage steps followed by N decreasing voltage steps on the output path in a charge-discharge cycle of the control gate.

Example 13 includes the apparatus of Example 12, wherein the switch coupled to the first flying capacitor and the output path is closed to transfer charge from the first flying capacitor to the control gate during a respective step of the N≥2 increasing voltage steps, and to transfer charge to the first flying capacitor from the control gate during a respective step of the N≥2 decreasing voltage steps.

Example 14 includes the apparatus of Example 12 or 13, wherein: the first flying capacitor is capable of storing a first intermediate voltage; the power supply node is capable of providing a peak drive voltage; and the N≥2 increasing voltage steps comprise the first intermediate voltage followed by the peak drive voltage and the N≥2 decreasing voltage steps comprise the first intermediate voltage followed by a ground voltage.

Example 15 includes the apparatus of any one of Examples 12-14, further comprising: a second flying capacitor; and a switch coupled to the second flying capacitor and the output path, wherein the switches are capable of providing N≥3 increasing voltage steps followed by N≥3 decreasing voltage steps on the output path in the charge-discharge cycle of the control gate.

Example 16 includes the apparatus of Example 15, wherein: the first flying capacitor is capable of storing a first intermediate voltage; the power supply node is capable of providing a peak drive voltage; the second flying capacitor is capable of storing a second intermediate voltage; the N≥3 increasing voltage steps comprise the first intermediate voltage followed by the second intermediate voltage followed by the peak drive voltage; and the N≥3 decreasing voltage steps comprise the second intermediate voltage followed by the first intermediate voltage followed by a ground voltage.

Example 17 includes an apparatus, comprising: a charge-recycling circuit coupled to a power source, wherein the charge-recycling circuit is capable of providing one or more intermediate voltages, and the voltage source is capable of providing a peak drive voltage; a multi-level driver coupled to the charge-recycling circuit, wherein the multi-level driver comprises a set of switches; and a power switch coupled to the set of switches, wherein the set of switches is capable of providing, to a control gate of the power switch, an increasing voltage staircase followed by a decreasing voltage staircase, and wherein the increasing voltage staircase comprises a ground voltage followed by the one or more intermediate voltages followed by the peak drive voltage and the decreasing voltage staircase comprises the one or more intermediate voltages followed by the ground voltage.

Example 18 includes the apparatus of Example 17, wherein the charge-recycling circuit comprises a push-pull regulation circuit for each intermediate voltage of the one or more intermediate voltages.

Example 19 includes the apparatus of Example 18, wherein: each push-pull regulation circuit comprises an n-type metal-oxide-semiconductor field-effect transistor (MOSFET) coupled serially to a p-type MOSFET, a path coupled to a source of the n-type MOSFET and a source of the p-type MOSFET, and first and second comparators coupled to control gates of the n-type MOSFET and the p-type MOSFET; and the first and second comparators are to apply voltages to the control gates of the n-type MOSFET and the p-type MOSFET to regulate a voltage of the path to an intermediate voltage of the one or more intermediate voltages.

Example 20 includes the apparatus of any one of Examples 17-19, wherein the charge-recycling circuit comprises a flying capacitor for each intermediate voltage of the one or more intermediate voltages.

Example 21 includes a method, comprising: providing, to a control gate of a power switch, an increasing voltage staircase followed by a decreasing voltage staircase, wherein: the increasing voltage staircase comprises a ground voltage followed by one or more intermediate voltages followed by the peak drive voltage and the decreasing voltage staircase comprises the one or more intermediate voltages followed by the ground voltage; a charge-recycling circuit coupled to a power source is capable of providing the one or more intermediate voltages; and the voltage source is capable of providing the peak drive voltage.

Example 22 includes the method of claim 21, wherein the providing the increasing voltage staircase followed by the decreasing voltage staircase comprises controlling a set of switches of a multi-level driver coupled to the charge-recycling circuit and the voltage source.

Example 23 includes a non-transitory machine-readable storage including machine-readable instructions that, when executed, cause a processor or other circuit or computing device to implement the method of claim 21 or 22.

Example 24 includes a computer program comprising instructions which, when the program is executed by a computer, cause the computer to carry out the method of claim 21 or 22. In the present detailed description, reference is made to the accompanying drawings that form a part hereof wherein like numerals designate like parts throughout, and in which is shown by way of illustration embodiments that may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order than the described embodiment. Various additional operations may be performed and/or described operations may be omitted in additional embodiments.

The terms “substantially,” “close,” “approximately,” “near,” and “about,” generally refer to being within +/−10% of a target value. Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

For the purposes of the present disclosure, the phrases “A and/or B” and “A or B” mean (A), (B), or (A and B). For the purposes of the present disclosure, the phrase “A, B, and/or C” means (A), (B), (C), (A and B), (A and C), (B and C), or (A, B, and C).

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

As used herein, the term “circuitry” may refer to, be part of, or include an Application Specific Integrated Circuit (ASIC), an electronic circuit, a processor (shared, dedicated, or group), a combinational logic circuit, and/or other suitable hardware components that provide the described functionality. As used herein, “computer-implemented method” may refer to any method executed by one or more processors, a computer system having one or more processors, a mobile device such as a smartphone (which may include one or more processors), a tablet, a laptop computer, a set-top box, a gaming console, and so forth.

The terms “coupled,” “communicatively coupled,” along with derivatives thereof are used herein. The term “coupled” may mean two or more elements are in direct physical or electrical contact with one another, may mean that two or more elements indirectly contact each other but still cooperate or interact with each other, and/or may mean that one or more other elements are coupled or connected between the elements that are said to be coupled with each other. The term “directly coupled” may mean that two or more elements are in direct contact with one another. The term “communicatively coupled” may mean that two or more elements may be in contact with one another by a means of communication including through a wire or other interconnect connection, through a wireless communication channel or link, and/or the like.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included. If the specification or claim refers to “a” or “an” element, that does not mean there is only one of the elements. If the specification or claims refer to “an additional” element, that does not preclude there being more than one of the additional elements.

Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

While the disclosure has been described in conjunction with specific embodiments thereof, many alternatives, modifications and variations of such embodiments will be apparent to those of ordinary skill in the art in light of the foregoing description. The embodiments of the disclosure are intended to embrace all such alternatives, modifications, and variations as to fall within the broad scope of the appended claims.

In addition, well-known power/ground connections to integrated circuit (IC) chips and other components may or may not be shown within the presented figures, for simplicity of illustration and discussion, and so as not to obscure the disclosure. Further, arrangements may be shown in block diagram form in order to avoid obscuring the disclosure, and also in view of the fact that specifics with respect to implementation of such block diagram arrangements are highly dependent upon the platform within which the present disclosure is to be implemented (i.e., such specifics should be well within purview of one skilled in the art). Where specific details (e.g., circuits) are set forth in order to describe example embodiments of the disclosure, it should be apparent to one skilled in the art that the disclosure can be practiced without, or with variation of, these specific details. The description is thus to be regarded as illustrative instead of limiting.

An abstract is provided that will allow the reader to ascertain the nature and gist of the technical disclosure. The abstract is submitted with the understanding that it will not be used to limit the scope or meaning of the claims. The following claims are hereby incorporated into the detailed description, with each claim standing on its own as a separate embodiment.

What is claimed is:

1. An apparatus, comprising:
a supply path coupled to a voltage source;
a first switch coupled to an output path and the supply path;
first and second transistors coupled to one another serially, wherein the first and second transistors are capable of regulating a voltage of a first regulated path coupled between the first and second transistors to a first intermediate voltage;
a second switch coupled to the output path and to the first regulated path; and
a third switch coupled to ground and to the output path; wherein:
the first switch is capable of coupling a peak drive voltage of the voltage source to the output path;
the second switch is capable of coupling the first intermediate voltage to the output path; and
the third switch is capable of grounding the output path.

2. The apparatus of claim 1, wherein:
the output path is coupled to a control gate of a power switch; and
the first, second and third switches are capable of providing N≥2 increasing voltage steps followed by N decreasing voltage steps on the output path in a charge-discharge cycle of the control gate.

3. The apparatus of claim 2, wherein the N≥2 increasing voltage steps comprise the first intermediate voltage followed by the peak drive voltage and the N≥2 decreasing voltage steps comprise the first intermediate voltage followed by a ground voltage.

4. The apparatus of claim 1, further comprising:
a first comparator coupled to a control gate of the first transistor; and
a second comparator coupled to a control gate of the second transistor; wherein:
the first comparator has a non-inverting input coupled to a reference voltage minus a hysteresis increment and an inverting input coupled to the first regulated path; and
the second comparator has a non-inverting input coupled to the reference voltage plus the hysteresis increment, and an inverting input coupled to the first regulated path.

5. The apparatus of claim 1, wherein the first and second transistors are in a push-pull configuration.

6. The apparatus of claim 1, wherein the first transistor comprises an n-type metal-oxide-semiconductor field-effect transistor (MOSFET) and the second transistor comprises a p-type MOSFET.

7. The apparatus of claim 1, further comprising:
third and fourth transistors coupled to one another serially, wherein the third and fourth transistors are capable of regulating a voltage of a second regulated path coupled between the third and fourth transistors to a second intermediate voltage; and
an additional switch coupled to the output path and to the second regulated path, wherein the additional switch is capable of coupling the second intermediate voltage to the output path.

8. The apparatus of claim 7, wherein:
the output path is coupled to a control gate of a power switch; and
the first, second and third switches and the additional switch are capable of providing N≥3 increasing voltage steps followed by N≥3 decreasing voltage steps on the output path in a charge-discharge cycle of the control gate.

9. The apparatus of claim 8, wherein:
the N≥3 increasing voltage steps comprise the first intermediate voltage followed by the second intermediate voltage followed by the peak drive voltage; and
the N≥3 decreasing voltage steps comprise the second intermediate voltage followed by the first intermediate voltage followed by a ground voltage.

10. The apparatus of claim 1, further comprising:
a first capacitor coupled in parallel with the first transistor, between the supply path and the first regulated path; and
a second capacitor coupled in parallel with the second transistor, between the first regulated path and a ground node.

11. The apparatus of claim 1, further comprising at least one of a voltage converter, an integrated circuit, a System on Chip, a System in Package or a computing device in which the supply path, the first switch, the first and second transistors, the second switch, and the third switch are provided.

12. An apparatus, comprising:
a switch coupled to a power supply node and to an output path;
a first flying capacitor;
a switch coupled to the first flying capacitor and the output path; and
a switch coupled to the output path and ground, wherein:
the output path is coupled to a control gate of a power switch; and
the switches are capable of providing N≥2 increasing voltage steps followed by N decreasing voltage steps on the output path in a charge-discharge cycle of the control gate.

13. The apparatus of claim 12, wherein the switch coupled to the first flying capacitor and the output path is closed to transfer charge from the first flying capacitor to the control gate during a respective step of the N≥2 increasing voltage steps, and to transfer charge to the first flying capacitor from the control gate during a respective step of the N≥2 decreasing voltage steps.

14. The apparatus of claim 12, wherein:
the first flying capacitor is capable of storing a first intermediate voltage;
the power supply node is capable of providing a peak drive voltage; and
the N≥2 increasing voltage steps comprise the first intermediate voltage followed by the peak drive voltage and the N≥2 decreasing voltage steps comprise the first intermediate voltage followed by a ground voltage.

15. The apparatus of claim 12, further comprising:
a second flying capacitor; and
a switch coupled to the second flying capacitor and the output path, wherein the switches are capable of providing N≥3 increasing voltage steps followed by N≥3 decreasing voltage steps on the output path in the charge-discharge cycle of the control gate.

16. The apparatus of claim 15, wherein:
the first flying capacitor is capable of storing a first intermediate voltage;
the power supply node is capable of providing a peak drive voltage;
the second flying capacitor is capable of storing a second intermediate voltage;
the N≥3 increasing voltage steps comprise the first intermediate voltage followed by the second intermediate voltage followed by the peak drive voltage; and
the N≥3 decreasing voltage steps comprise the second intermediate voltage followed by the first intermediate voltage followed by a ground voltage.

17. An apparatus, comprising:
a charge-recycling circuit coupled to a power source, wherein the charge-recycling circuit is capable of providing one or more intermediate voltages, and the voltage source is capable of providing a peak drive voltage;
a multi-level driver coupled to the charge-recycling circuit, wherein the multi-level driver comprises a set of switches; and
a power switch coupled to the set of switches, wherein the set of switches is capable of providing, to a control gate of the power switch, an increasing voltage staircase followed by a decreasing voltage staircase, and wherein the increasing voltage staircase comprises a ground voltage followed by the one or more intermediate voltages followed by the peak drive voltage and the decreasing voltage staircase comprises the one or more intermediate voltages followed by the ground voltage.

18. The apparatus of claim 17, wherein the charge-recycling circuit comprises a push-pull regulation circuit for each intermediate voltage of the one or more intermediate voltages.

19. The apparatus of claim 18, wherein:
each push-pull regulation circuit comprises an n-type metal-oxide-semiconductor field-effect transistor (MOSFET) coupled serially to a p-type MOSFET, a path coupled to a source of the n-type MOSFET and a source of the p-type MOSFET, and first and second comparators coupled to control gates of the n-type MOSFET and the p-type MOSFET; and
the first and second comparators are to apply voltages to the control gates of the n-type MOSFET and the p-type MOSFET to regulate a voltage of the path to an intermediate voltage of the one or more intermediate voltages.

20. The apparatus of claim 17, wherein the charge-recycling circuit comprises a flying capacitor for each intermediate voltage of the one or more intermediate voltages.
